(19) United States
(12) Patent Application Publication
(10) Pub. No.: US 2026/0101518 A1
(43) Pub. Date: Apr. 9, 2026

(54) SEMICONDUCTOR DEVICE

(71) Applicant: Samsung Electronics Co., Ltd., Suwon-si (KR)

(72) Inventors: Miso SHIN, Suwon-si (KR); Hansol KANG, Suwon-si (KR)

(73) Assignee: Samsung Electronics Co., Ltd., Suwon-si (KR)

(21) Appl. No.: 19/211,667

(22) Filed: May 19, 2025

(30) Foreign Application Priority Data
Oct. 8, 2024 (KR) 10-2024-0136951

(51) Int. Cl. H01L 23/00; H01L 25/065; H01L 25/18; H10B 80/00

(52) U.S. Cl. CPC H10B 80/00; H10W 90/00; H10W 72/926; H10W 72/963; H10W 72/967; H10W 90/792

(57) ABSTRACT

The present disclosure relates to semiconductor devices, and semiconductor devices according to example embodiments include a first substrate structure and a second substrate structure on the first substrate structure, the first substrate structure including a first substrate including a cell area and a scribe lane area surrounding the cell area, first bonding pads over the cell area of the first substrate, and first dummy pads on the first substrate in the scribe lane area, the second substrate structure including a second substrate on the first substrate, and second bonding pads between the first substrate and the second substrate, joined with the plurality of first bonding pads, and a sum of the areas of the first dummy pads per a unit area in the scribe lane area is greater than or equal to a sum of the areas of the first bonding pads per a unit area in the cell area.

### CROSS-REFERENCE TO RELATED APPLICATION

This application claims priority to and the benefit of Korean Patent Application No. 10-2024-0136951 filed in the Korean Intellectual Property Office on Oct. 8, 2024, the entire contents of which are incorporated herein by reference.

### BACKGROUND OF THE DISCLOSURE

### 1. Field of the Disclosure

The present disclosure relates to a semiconductor device.

### 2. Description of the Related Art

In electron systems that utilize data storage, semiconductor devices capable of storing high-capacity data may be beneficial. Accordingly, methods to increase the data storage capacity of the semiconductor devices are being researched. For example, as one of the methods for increasing the data storage capacity of the semiconductor device, semiconductor devices including memory cells arranged three-dimensionally instead of two-dimensionally are being proposed.

### SUMMARY OF THE DISCLOSURE

Example embodiments aim to provide semiconductor devices that may improve performance and reliability.

A semiconductor device according to some example embodiments includes a first substrate structure and a second substrate structure on the first substrate structure, the first substrate structure including a first substrate including a cell area and a scribe lane area surrounding the cell area, a plurality of first bonding pads over the cell area of the first substrate, and a plurality of first dummy pads on the first substrate in the scribe lane area, the second substrate structure including a second substrate on the first substrate, and a plurality of second bonding pads between the first substrate and the second substrate, and joined with the plurality of first bonding pads to each other, and the sum of the areas of the plurality of first dummy pads per a unit area in the scribe lane area is greater than or equal to the sum of the areas of the plurality of first bonding pads per a unit area in the cell area.

A semiconductor device according to some example embodiments includes a first substrate structure and a second substrate structure above the first substrate structure, the first substrate structure including a first substrate including a plurality of cell areas and a scribe lane area positioned between the plurality of cell areas, a plurality of first bonding pads on the first substrate in the plurality of cell areas, a plurality of first dummy pads above the first substrate in the scribe lane area, and a first junction insulation layer surrounding the plurality of first bonding pads and the plurality of first dummy pads, the second substrate structure including a second substrate on the first substrate, a plurality of second bonding pads between the first substrate and the second substrate and joined with the plurality of first bonding pads each other, and a second junction insulation layer surrounding the plurality of second bonding pads and joined with at least a portion of an upper surface of the first junction insulation layer, and a sum of the areas of the plurality of first dummy pads per a unit area in the cell area is greater than or equal to a sum of the areas of the plurality of first bonding pads per a unit area.

A semiconductor device according to some example embodiments includes a first substrate structure and a second substrate structure above the first substrate structure, the first substrate structure including a first substrate including a cell area and a scribe lane area surrounding the cell area, a plurality of first bonding pads above the cell area of the first substrate, a plurality of first dummy pads above the scribe lane area of the first substrate, and a first junction insulation layer surrounding the plurality of first bonding pads and the plurality of first dummy pads, the second substrate structure including a second substrate on the first substrate, a plurality of second bonding pads between the first substrate and the second substrate and joined with the plurality of first bonding pads each other, and a second junction insulation layer surrounding a plurality of second bonding pads and junction with at least a portion of an upper surface of the first junction insulation layer in the cell area, the first junction insulation layer including a recessed portioned concave toward the first substrate in the scribe lane area, and a thickness of at least some of the plurality of first dummy pads is less than a thickness of the plurality of first bonding pads.

According to some example embodiments, a method of manufacturing a semiconductor device may include polishing a first substrate structure, the first substrate structure including a first substrate including a cell area and a scribe lane area surrounding the cell area, a plurality of first bonding pads over the cell area of the first substrate, and a plurality of first dummy pads on the first substrate in the scribe lane area, polishing a second substrate structure, the second substrate structure including a second substrate on the first substrate, and a plurality of second bonding pads between the first substrate and the second substrate, and joining the first substrate structure to the second substrate structure aligned along the cell areas and the scribe lane areas, wherein a sum of the areas of the plurality of first dummy pads per a unit area in the scribe lane area is greater than or equal to a sum of the areas of the plurality of first bonding pads per a unit area in the cell area.

According to some example embodiments, the scribe lane area of each of the first and second substrates may include a greater number of dummy pads than a number of bonding pads in the cell areas of each of the first and second substrates.

According to some example embodiments, reliability of semiconductor devices may be improved.

### BRIEF DESCRIPTION OF THE DRAWINGS

FIG. 1 is a top plan view showing a wafer in which semiconductor devices are implemented according to some example embodiments.

FIG. 2 is a top plan view showing a cell area and a scribe lane area of a semiconductor device according to some example embodiments.

FIG. 3 is a cross-sectional view showing a cell area and a scribe lane area of a semiconductor device according to some example embodiments.

FIG. 4 is an enlarged cross-sectional view of an area S1 of FIG. 3.

FIG. 5 to FIG. 7 are top plan views illustrating a plurality of first dummy pads of a semiconductor device according to some example embodiments.

FIG. 8 to FIG. 11 are cross-sectional views showing a cell area and a scribe lane area of a semiconductor device according to some example embodiments.

FIG. 12 to FIG. 14 are top plan views showing a cell area and a scribe lane area of a semiconductor device according to some example embodiments.

FIG. 15 and FIG. 16 are top plan views illustrating a cell area, a key area, and a first division area of a semiconductor device according to some example embodiments.

FIG. 17 is a cross-sectional view schematically illustrating a semiconductor device according to some example embodiments.

FIG. 18 is a cross-sectional view illustrating a channel structure of a semiconductor device according to some example embodiments.

FIG. 19 and FIG. 20 are cross-sectional views illustrating a channel structure of a semiconductor device according to some example embodiments.

FIG. 21 is a schematic view of an electron system including a semiconductor device according to some example embodiments.

FIG. 22 is a perspective view schematically illustrating an electron system including a semiconductor device according to some example embodiments.

### DETAILED DESCRIPTION

The present disclosure will be described more fully hereinafter with reference to the accompanying drawings, in which example embodiments of the disclosure are shown. As those skilled in the art would realize, the described example embodiments may be modified in various different ways, all without departing from the spirit or scope of the present disclosure.

Descriptions of parts not relating to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. For better understanding and ease of description and/or for simpler illustration, the thickness of some layers and areas is enlarged or exaggerated.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” means viewing a target portion from the top, and the phrase “in a cross-sectional view” means viewing a cross-section formed by vertically cutting a target portion from the side.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

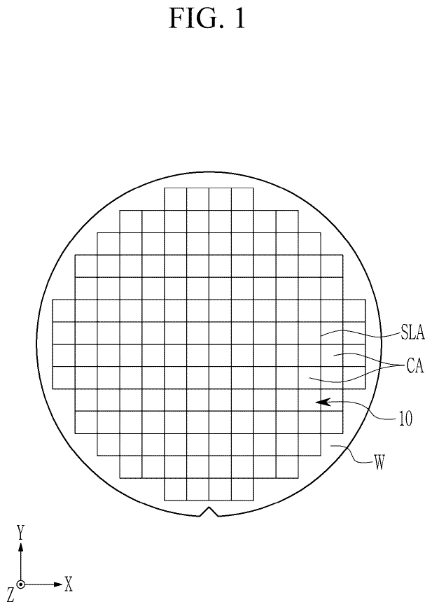

Hereinafter, a semiconductor device according to some example embodiments of the present disclosure will be described with reference to FIG. 1.

FIG. 1 is a top plan view showing a wafer having semiconductor devices implemented according to some example embodiments.

Referring to FIG. 1, a wafer W having semiconductor devices implemented according to some example embodiments may include a cell area CA in which a plurality of semiconductor devices 10 are positioned and a scribe lane area SLA that demarcates the plurality of semiconductor devices 10.

The cell area CA may be surrounded by the scribe lane area SLA. The cell area CA may be partitioned by the scribe lane area SLA. In some example embodiments, the semiconductor devices 10 may be positioned in each cell area CA partitioned by the scribe lane area SLA. Here, the cell area CA may refer to an area where the semiconductor device 10 is positioned, and the scribe lane area SLA may refer to a dicing area for separating the semiconductor devices 10 formed on the wafer W.

The scribe lane area SLA may extend along a first direction (a direction X) and a second direction (a direction Y). The scribe lane area SLA may be extended along the first direction (the direction X) and the second direction (the direction Y) to partition the cell area CA. Accordingly, the plurality of cell areas CA may be defined by the scribe lane area SLA. The plurality of cell areas CA may be arranged spaced apart along the first direction (the direction X) and the second direction (the direction Y) on the wafer W. In some example embodiments, the scribe lane area SLA may have a plurality of first dummy pads 360 and a plurality of second dummy pads 460 positioned therein.

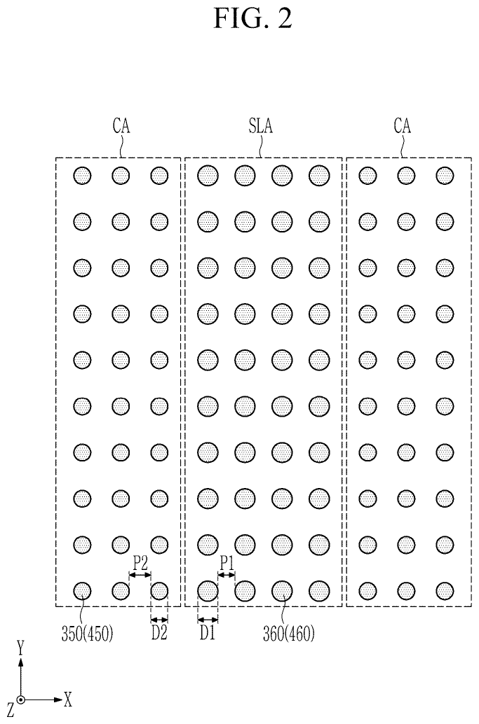

Hereinafter, the semiconductor device according to some example embodiments is described with reference to FIG. 2 to FIG. 4.

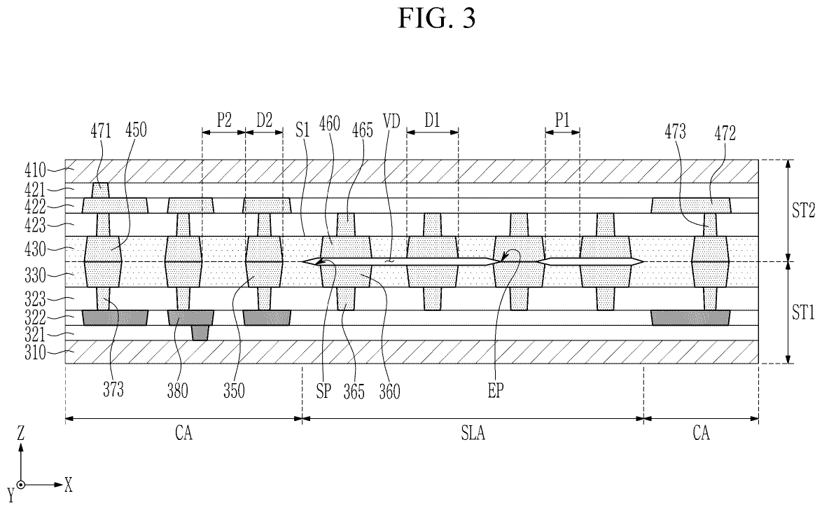

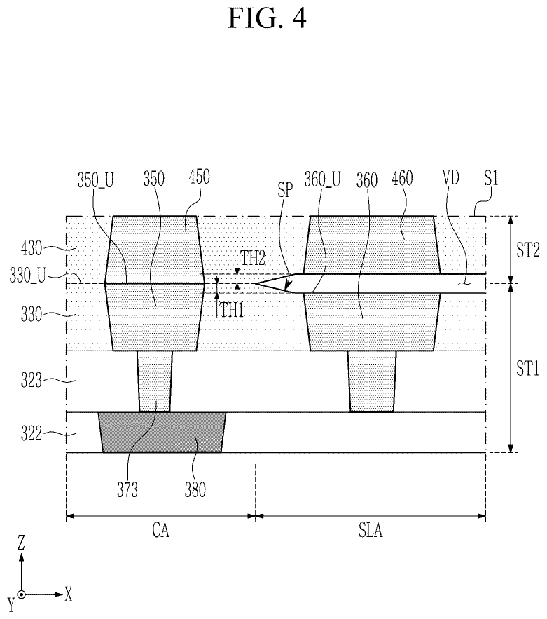

FIG. 2 is a top plan view showing a cell area and a scribe lane area of a semiconductor device according to some example embodiments. FIG. 3 is a cross-sectional view showing a cell area and a scribe lane area of a semiconductor device according to some example embodiments. FIG. 4 is an enlarged cross-sectional view of an area S1 of FIG. 3.

Referring to FIG. 2 to FIG. 4, a semiconductor device according to some example embodiments may include a first substrate structure ST1 and a second substrate structure ST2 positioned on the first substrate structure ST1.

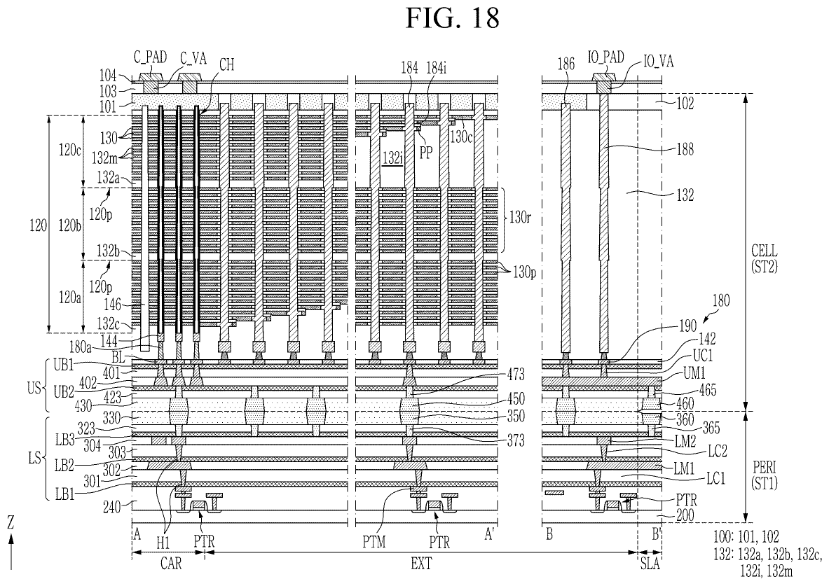

The first substrate structure ST1 and the second substrate structure ST2 may be a semiconductor device joined by a C2C (Cu to Cu) wafer bonding method. In some example embodiments, the first substrate structure ST1 and the second substrate structure ST2 may be a semiconductor device joined by a hybrid copper bonding (HCB) method. The first substrate structure ST1 and the second substrate structure ST2 may include a 3-dimensional semiconductor memory device or a 3D semiconductor package. For example, each of the first substrate structure ST1 and the second substrate structure ST2 may be a portion corresponding to at least a portion of a peripheral structure (PERI of FIG. 18) and a cell structure (CELL of FIG. 18) of the semiconductor device illustrated in FIG. 18. However, it is not limited thereto, and the first substrate structure ST1 and the second substrate structure ST2 may be applied to all semiconductor devices including structures joined by a hybrid copper bonding (HCB) method.

In some example embodiments, the first substrate structure ST1 may include one surface and the other surface facing each other. One surface of the first substrate structure ST1 may be a surface facing the second substrate structure ST2, and the other surface of the first substrate structure ST1 may be an opposite surface of the one surface of the first substrate structure ST1. Here, one surface of the first substrate structure ST1 may mean a front side or an upper surface of the first substrate structure ST1, and the other surface of the first substrate structure ST1 may mean a back side or a lower surface of the first substrate structure ST1. Additionally, the second substrate structure ST2 may include one surface and the other surface facing each other. One surface of the second substrate structure ST2 may be a surface facing the first substrate structure ST1, and the other surface of the second substrate structure ST2 may be an opposite surface of the one surface of the second substrate structure ST2.

In some example embodiments, one surface of the first substrate structure ST1 adjacent to the second substrate structure ST2 may be a junction surface with the second substrate structure ST2. Additionally, one surface of the second substrate structure ST2 adjacent to the first substrate structure ST1 may be a junction surface with the first substrate structure ST1. That is, one surface of the first substrate structure ST1 and one surface of the second substrate structure ST2 may be junction surfaces between the first substrate structure ST1 and the second substrate structure ST2. At this time, one surface of the first substrate structure ST1 and one surface of the second substrate structure ST2 may be joined by a hybrid bonding. The explanation of this will be given later.

According to some example embodiments, the first substrate structure ST1 of the semiconductor device may include a first substrate 310 including a cell area CA and a scribe lane area SLA surrounding the cell area CA, and a plurality of first bonding pads 350 and a plurality of first dummy pads 360 positioned on the first substrate 310.

The first substrate 310 may be a semiconductor substrate, such as a semiconductor wafer (W in FIG. 1). The first substrate 310 may be a bulk silicon substrate, a silicon-on-insulator (SOI) substrate, a germanium (Ge) substrate, a germanium-on-insulator (GOI) substrate, a silicon-germanium (Si—Ge) substrate, or a substrate of an epitaxial thin film obtained by performing a selective epitaxial growth (SEG). The first substrate 310 may include, for example, at least one of silicon (Si), germanium (Ge), silicon germanium (SiGe), gallium arsenic (GaAs), indium gallium arsenic (InGaAs), aluminum gallium arsenic (AlGaAs), or a mixture thereof. As another example, the first substrate 310 may be an insulating substrate, such as a printed circuit board (PCB).

The first substrate 310 may include the cell area CA and the scribe lane area SLA surrounding the cell area CA. The semiconductor device (10 of FIG. 1) including the memory cell, etc. may be positioned in the cell area CA of the first substrate 310. For example, a 3-dimensional semiconductor memory device may be positioned in the cell area CA of the first substrate 310, but it is not limited thereto. In some example embodiments, the cell area CA may be provided in multiple numbers. The plurality of cell area CAs may be arranged spaced apart from each other along the first direction (the direction X) and the second direction (the direction Y). The scribe lane area SLA may be positioned between the plurality of cell areas CA. The plurality of cell areas CA may be defined by the scribe lane area SLA.

The scribe lane area SLA may surround the cell area CA. The scribe lane area SLA may extend in the first direction (the direction X) and the second direction (the direction Y) to surround the cell area CA. The plurality of cell area CAs may be separated by the scribe lane area SLA. The scribe lane area SLA may be a dicing area for separating the semiconductor devices 10 formed on the wafer (W in FIG. 1).

The first substrate structure ST1 of the semiconductor device according to some example embodiments may further include a plurality of lower insulation layers 321, 322, and 323 positioned on the first substrate 310.

The first to third lower insulation layers 321, 322, and 323 may be sequentially positioned on the first substrate 310. That is, the first lower insulation layer 321 may be positioned on the first substrate 310, the second lower insulation layer 322 may be positioned on the first lower insulation layer 321, and the third lower insulation layer 323 may be positioned on the second lower insulation layer 322. The first to third lower insulation layers 321, 322, and 323 may include various insulating materials. The first to third lower insulation layers 321, 322, and 323 may include the same material, but is not limited thereto. For example, the first to third lower insulation layers 321, 322, and 323 can include silicon oxide, but is not limited thereto, the first to third lower insulation layers 321, 322, and 323 may each include at least one of silicon oxynitride, silicon carbon oxynitride, and silicon carbon nitride.

FIG. 3 illustrates a case where the number of the lower insulation layers 321, 322, and 323 is three, but it is not limited thereto. As an example, the first substrate structure ST1 may include four or more lower insulation layers. As another example, the first substrate structure ST1 may include two or fewer lower insulation layers.

In FIG. 3, it is shown that the second lower insulation layer 322 is positioned directly on the upper surface of the first lower insulation layer 321, and the third lower insulation layer 323 is positioned directly on the upper surface of the second lower insulation layer 322, but it is not limited thereto. For example, the first substrate structure ST1 may further include a lower barrier layer positioned between any of the first to third lower insulation layers 321, 322, and 323. The lower barrier layer may act as a barrier to prevent or reduce materials forming a plurality of first bonding pads 350, a plurality of first dummy pads 360, a first bonding via 373, and a first dummy via 365, which will be described later from diffusing to the surroundings during the process of forming a lower wire 380, the plurality of first bonding pads 350, the plurality of first dummy pads 360, the first bonding via 373, and the first dummy via 365. The lower barrier layer may include a different material than the first to third lower insulation layers 321, 322, and 323. For example, the lower barrier layer may include silicon nitride, but is not limited thereto, and may also include at least one of silicon oxynitride, silicon carbon oxynitride, and silicon carbon nitride.

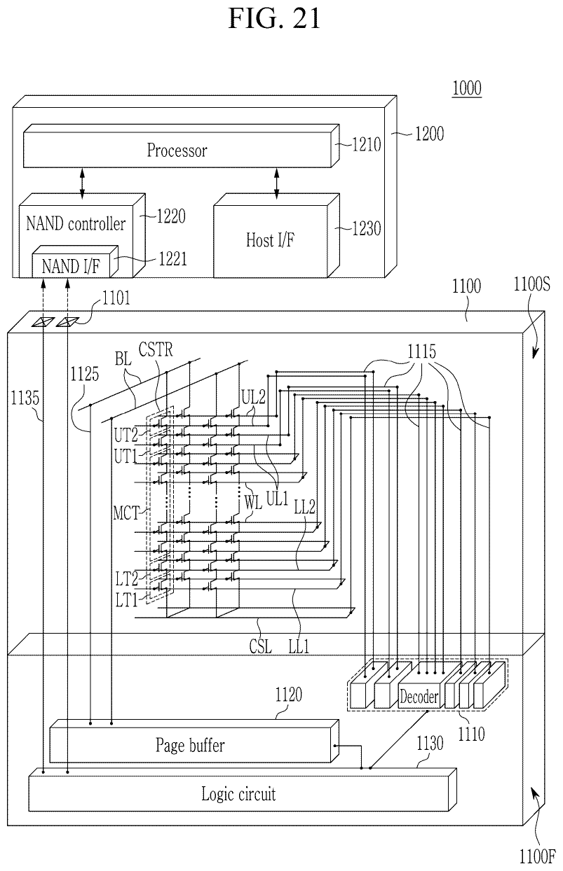

The first substrate structure ST1 of the semiconductor device according to some example embodiments may further include circuit elements positioned on the first substrate 310 in the cell area CA. The circuit components may be positioned in the cell area CA and may not be positioned in the scribe lane area SLA. The circuit components may be positioned within the plurality of lower insulation layers 321, 322, and 323, but is not limited thereto. The circuit components may control the operation of the semiconductor devices. For example, the circuit components may include a decoder circuit (a reference numeral 1110 of FIG. 21), a page buffer (a reference numeral 1120 of FIG. 21), a logic circuit (a reference numeral 1130 of FIG. 21) of a semiconductor memory device, etc. As another example, the circuit components may include not only active elements such as transistors, but also passive elements such as capacitors, resistors, and inductors.

The first substrate structure ST1 of the semiconductor device according to some example embodiments may further include a lower wire 380 positioned within the second lower insulation layer 322.

The lower wire 380 may be positioned above the first lower insulation layer 321. The lower wire 380 may penetrate the second lower insulation layer 322. The lower wire 380 may be surrounded by the second lower insulation layer 322. The lower wire 380 may be positioned between the first lower insulation layer 321 and the third lower insulation layer 323, but is not limited thereto.

The lower wire 380 may be positioned in the cell area CA and may not be positioned in the scribe lane area SLA. The lower wire 380 may be positioned between the first substrate 310 and a first bonding pads 350, which will be described later, in the cell area CA. In some example embodiments, the lower wire 380 may be connected to various circuit elements that control the operation of the semiconductor device in the cell area CA. That is, the lower wire 380 may mean a wiring connected to a circuit element that controls the operation of the semiconductor device. Here, the circuit element may mean a peripheral circuit structure such as a decoder circuit (a reference numeral 1110 of FIG. 21), a page buffer (a reference numeral 1120 of FIG. 21), a logic circuit (a reference numeral 1130 of FIG. 21), but is not limited thereto.

In FIG. 3, the lower wire 380 is described as being positioned on the first lower insulation layer 321, but the arrangement of the lower wire 380 may be variously changed within the range between the first substrate 310 and the first bonding pads 350 in the cell area CA.

Referring further to FIG. 4, the plurality of first bonding pads 350 may be positioned over the cell area CA of the first substrate 310. The plurality of first bonding pads 350 may mean pads penetrating the first junction insulation layer 330 and positioned in the cell area CA. That is, the plurality of first bonding pads 350 may be positioned on the third lower insulation layer 323 in the cell area CA. The plurality of first bonding pads 350 may penetrate the first junction insulation layer 330. In the cell area CA, the plurality of first bonding pads 350 may be positioned in the same layer as the first junction insulation layer 330. For example, in the cell area CA, the upper surface 350_U of the plurality of first bonding pads 350 may be positioned at substantially the same or the same level as an upper surface 330_U of a first junction insulation layer 330, which will be described later. The thickness of the plurality of first bonding pads 350 along the third direction (the direction Z) may be substantially the same or the same as a thickness of a first junction insulation layer 330, which will be described later, along the third direction (the direction Z), but is not limited thereto. The plurality of first bonding pads 350 may overlap the lower wire 380 in the third direction (the direction Z), but is not limited thereto.

The plurality of first bonding pads 350 may be joined to the plurality of second bonding pads 450 of the second substrate structure ST2 by a hybrid bonding. The plurality of first bonding pads 350 may be joined in direct contact with the plurality of second bonding pads 450 of the second substrate structure ST2 to form a metal junction. That is, the upper surface 350_U of the plurality of first bonding pads 350 may form a junction surface where the first substrate structure ST1 and the second substrate structure ST2 are joined. For example, the plurality of first bonding pads 350 may be joined to the plurality of second bonding pads 450 of the second substrate structure ST2 to form a part of the junction surface of the first substrate structure ST1 and the second substrate structure ST2. Accordingly, the first bonding pads 350 may be electrically connected to the plurality of second bonding pads 450 of the second substrate structure ST2. Additionally, the plurality of first bonding pads 350 may be positioned between the lower wire 380 and the second substrate structure ST2. The plurality of first bonding pads 350 may be electrically connected to the lower wire 380 through the first bonding via 373.

In some example embodiments, the plurality of first bonding pads 350 may have a second the width D2. Additionally, the plurality of first bonding pads 350 may be arranged with a second interval P2. That is, the minimum distance between the plurality of first bonding pads 350 adjacent in the first direction (the direction X) may have the second interval P2. The sum of the areas of the plurality of first bonding pads 350 per a unit area of the cell area CA on a plane may be defined as ‘a second metal density’ of the cell area CA. The second metal density of the cell area CA may be determined by the second width D2 and the second interval P2 of the plurality of first bonding pads 350. For example, as the second the width D2 of the plurality of first bonding pads 350 of the cell area CA increases, the second metal density may increase. Additionally, as the second interval P2 of the plurality of first bonding pads 350 of the cell area CA decreases, the second metal density may increase.

For better understanding and ease of explanation, in the following, the sum of the areas of the plurality of first bonding pads 350 per a unit area of the cell area CA on a plane is referred to as ‘the second metal density’ of the cell area CA. For example, the second metal density of the cell area CA may be about or exactly 25%, but is not limited thereto.

The plurality of first bonding pads 350 may include a conductive material. For example, the plurality of first bonding pads 350 may include copper (Cu). However, but it is not limited thereto, the plurality of first bonding pads 350 may include a conductive material such as tungsten (W) or aluminum (Al).

The plurality of first dummy pads 360 may be positioned on the scribe lane area SLA of the first substrate 310. The plurality of first dummy pads 360 may refer to pads positioned in the scribe lane area SLA and penetrating the first junction insulation layer 330. That is, the plurality of first dummy pads 360 may be positioned on the third lower insulation layer 323 in the scribe lane area SLA. The plurality of first dummy pads 360 may penetrate the first junction insulation layer 330. The plurality of first dummy pads 360 may be electrically floating from the lower wire 380 and the first substrate 310. Additionally, the plurality of first dummy pads 360 may be electrically floating from the plurality of first bonding pads 350. That is, the lower surface of the plurality of first dummy pads 360 may be in contact with the second lower insulation layer 322.

In the scribe lane area SLA, the plurality of first dummy pads 360 may be positioned in the same layer as the first junction insulation layer 330. For example, in the scribe lane area SLA, the upper surface 360_U of the plurality of first dummy pads 360 may be positioned at substantially the same or the same level as an upper surface 330_U of a first junction insulation layer 330, which will be described later, but is not limited thereto. As another example, the upper surface 360_U of a plurality of first dummy pads 360 may be positioned at a higher level or lower level than the upper surface 330_U of the first junction insulation layer 330, which will be described later. This may be due to an erosion phenomenon caused by polishing (for example, an excessive or over polishing) of the plurality of first dummy pads 360 and/or the first junction insulation layer 330 during a planarization process of the upper surfaces of the plurality of first dummy pads 360 and the first junction insulation layer 330 through a chemical mechanical polishing (CMP) process. The detailed description thereof this will be given later in the description of the first junction insulation layer 330.

The plurality of first dummy pads 360 may be positioned in the same layer as the plurality of first bonding pads 350. The plurality of first dummy pads 360 may not overlap the lower wire 380 in the third direction (the direction Z), but is not limited thereto.

In some example embodiments, the plurality of first dummy pads 360 may have the first width D1. Additionally, the plurality of first dummy pads 360 may be arranged with the first interval P1. That is, the minimum distance between the plurality of adjacent first dummy pads 360 in the first direction (the direction X) may have the first interval P1. At this time, the sum of the areas of the plurality of first dummy pads 360 of the scribe lane area SLA on a plane per a unit area may be defined as ‘a first metal density’ of the scribe lane area SLA. The first metal density of the scribe lane area SLA may be determined by the first width D1 and the first interval P1 of the plurality of first dummy pads 360. For example, as the width D1 of the first dummy pads 360 of the scribe lane area SLA increases, the first metal density can increase. Additionally, as the first interval P1 of the plurality of first dummy pads 360 of the scribe lane area SLA decreases, the first metal density can increase.

For better understanding and ease of explanation, in the following, the sum of the areas of the plurality of first dummy pads 360 of the scribe lane area SLA on a plane per a unit area is referred to as ‘the first metal density’ of the scribe lane area SLA. For example, the first metal density of the scribe lane area SLA may be greater than about or exactly 25%, but is not limited thereto.

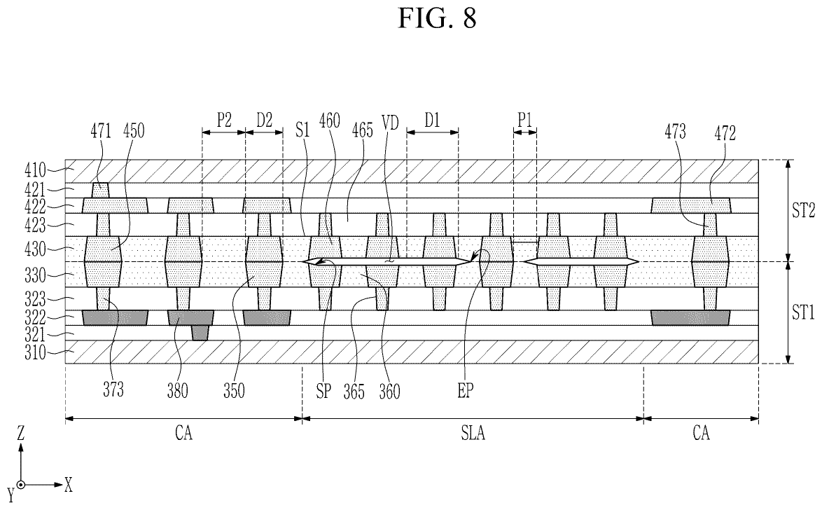

The first metal density of the scribe lane area SLA may be greater than or equal to the second metal density of the cell area CA. For example, as illustrated in FIG. 2 to FIG. 4, the first the width D1 of the plurality of first dummy pads 360 positioned in the scribe lane area SLA may be greater than or equal to the second the width D2 of the plurality of first bonding pads 350 positioned in the cell area CA. Therefore, the sum of the areas of the plurality of first dummy pads 360 of the scribe lane area SLA per a unit area on a plane may be greater than or equal to the sum of the areas of the plurality of first bonding pads 350 of the cell area CA per a unit area. However, it is not limited thereto, the first interval P1 of the plurality of first dummy pads 360 positioned in the scribe lane area SLA may be smaller than the second interval P2 of the plurality of first bonding pads 350 positioned in the cell area CA. The description thereof will be given later with reference to FIG. 8.

In this range, when performing a chemical mechanical polishing (CMP) process to planarize the upper surface 360_U of the plurality of first dummy pads 360 and the upper surface 350_U of the plurality of first bonding pads 350, the plurality of first dummy pads 360 may be for example, polished or over polished (over grinded) more than the plurality of first bonding pads 350. Specifically, the polishing rate of the plurality of first dummy pads 360 and the plurality of first bonding pads 350 may be greater than a polishing rate of a first junction insulation layer 330, which will be explained later. As the sum of the areas of the plurality of first dummy pads 360 and the plurality of first bonding pads 350 increases compared to the area of the first junction insulation layer 330, the amount of the polishing may increase. Therefore, since the sum of the areas of the plurality of first dummy pads 360 of the scribe lane area SLA per unit area is greater than the sum of the areas of the plurality of first bonding pads 350 of the cell area CA per unit area, the polishing amount of the scribe lane area SLA, which has a high metal density, may be greater than that of the cell area CA. Additionally, an erosion of the first junction insulation layer 330 in the scribe lane area SLA may increase. The detailed description of this will be given later in the description of the first junction insulation layer 330.

Accordingly, as illustrated in FIG. 4, at least some of the upper surface 360_U of the plurality of first dummy pads 360 may be positioned at a lower level than the upper surface 350_U of the plurality of first bonding pads 350 in the third direction (Z direction). That is, at least some of the upper surface 360_U of the plurality of first dummy pads 360 may be positioned closer from the upper surface of the first substrate 310 than the upper surface 350_U of the plurality of first bonding pads 350. At least some of the plurality of first dummy pads 360 may be positioned within the recessed portion SP of the first junction insulation layer 330. A first thickness TH1 may be generated from the upper surface 350_U of the plurality of first bonding pads 350 to the upper surface 360_U of the plurality of first dummy pads 360. Accordingly, at least some of the plurality of first dummy pads 360 may be positioned apart from the plurality of second dummy pads 460 of the second substrate structure ST2 in the third direction (the direction Z). Additionally, the thickness of the plurality of first dummy pads 360 along the third direction (the direction Z) may be less than the thickness of the plurality of first bonding pads 350 along the third direction (the direction Z), but is not limited thereto. This may be due to the process characteristic that the plurality of first dummy pads 360 described above are polished (for example, an excessive or over polishing) more than the plurality of first bonding pads 350.

Meanwhile, in some example embodiments, another portion of the plurality of first dummy pads 360 may include a protruding portion EP that protrudes in the third direction (the direction Z). The protruding portion EP may mean a portion of the first dummy pads 360 that is protruded in the third direction (the direction Z) from the upper surface of the first junction insulation layer 330 positioned in the scribe lane area SLA among the plurality of first dummy pads 360. That is, at least some of the plurality of first dummy pads 360 may be protruded in the third direction (the direction Z) from the upper surface of the first junction insulation layer 330 positioned in the scribe lane area SLA. At this time, the protruding portion EP may be separated from the plurality of second dummy pads 460 in the third direction (the direction Z), or may be joined to the plurality of second dummy pads 460 of the second substrate structure ST2 by a hybrid bonding.

In summary, at least some of the upper surface 360_U of the plurality of first dummy pads 360 of the semiconductor device according to some example embodiments may be positioned at a lower level than the upper surface 350_U of the plurality of first bonding pads 350, accordingly, when the second substrate structure ST2 is joined to the first substrate structure ST1, in the scribe lane area SLA, the plurality of first dummy pads 360 and the second substrate structure ST2 may be spaced apart from each other along the third direction (the direction Z). Accordingly, even if there is the step such as the protruding portion EP in at least some of the plurality of first dummy pads 360, the first substrate structure ST1 and the second substrate structure ST2 may be joined (e.g., easily) without a gap occurring between them in the cell area CA. Therefore, the hybrid bonding quality of the semiconductor device according to some example embodiments may be improved.

The plurality of first dummy pads 360 may include a conductive material. The plurality of first dummy pads 360 may include the same material as the plurality of first bonding pads 350. The plurality of first dummy pads 360 may be formed simultaneously (e.g., at or about at the same time) by the same process as the plurality of first bonding pads 350. For example, the plurality of first dummy pads 360 may contain copper (Cu). However, it is not limited thereto, the plurality of first dummy pads 360 may include a conductive material such as tungsten (W) or aluminum (Al).

The first substrate structure ST1 of the semiconductor device according to some example embodiments may further include a first bonding via 373 positioned between the plurality of first bonding pads 350 and the lower wire 380 and a first dummy via 365 positioned on the lower surface of a plurality of first dummy pads 360.

The first bonding via 373 may be positioned in the cell area CA of the first substrate 310. The first bonding via 373 may mean a via connected to the plurality of first bonding pads 350 positioned in the cell area CA. The first bonding via 373 may be positioned between the lower wire 380 and the plurality of first bonding pads 350. The first bonding via 373 may penetrate the third lower insulation layer 323. The first bonding via 373 may be positioned over the second lower insulation layer 322. The first bonding via 373 may electrically connected the lower wire 380 and the plurality of first bonding pads 350.

In some example embodiments, the first bonding via 373 may include a conductive material. The first bonding via 373 may include the same material as the plurality of first bonding pads 350. The first bonding via 373 may be formed integrally by being formed in the same process as the plurality of first bonding pads 350. For example, first bonding via 373 may include copper (Cu), but is not limited thereto, it may also include conductive materials such as tungsten (W) or aluminum (Al). As the first bonding via 373 and the plurality of first bonding pads 350 are formed as one (e.g., integral), a boundary may not be recognized between the first bonding via 373 and the plurality of first bonding pads 350, but is not limited thereto.

The first dummy via 365 may be positioned in the scribe lane area SLA of the first substrate 310. The first dummy via 365 may mean a via connected to the plurality of first dummy pads 360 positioned in the scribe lane area SLA. The first dummy via 365 may penetrate the third lower insulation layer 323. The first bonding via 373 may be positioned over the second lower insulation layer 322. The first dummy via 365 may be electrically connected to the plurality of first dummy pads 360. The first dummy via 365 may be electrically floating from the lower wire 380 and the first substrate 310.

In some example embodiments, the first dummy via 365 may include a conductive material. The first dummy via 365 may include the same material as the plurality of first dummy pads 360. The first dummy via 365 may be formed integrally in the same process as the plurality of first dummy pads 360. For example, the first dummy via 365 may include copper (Cu), but is not limited thereto, it may also include conductive materials such as tungsten (W) or aluminum (Al). As the first dummy via 365 and the plurality of first dummy pads 360 are formed as one (e.g., integral), there may not be a boundary recognized between the first dummy via 365 and the plurality of first dummy pads 360, but is not limited thereto.

The semiconductor device according to some example embodiments may further include a first junction insulation layer 330 positioned over the third lower insulation layer 323.

The first junction insulation layer 330 may be positioned over the third lower insulation layer 323. The first junction insulation layer 330 may be positioned in the cell area CA and the scribe lane area SLA. The first junction insulation layer 330 may surround the plurality of first bonding pads 350 and the plurality of first dummy pads 360. The lower surface of the first junction insulation layer 330 may be in contact with the third lower insulation layer 323, but is not limited thereto.

In some example embodiments, the upper surface 330_U of the first junction insulation layer 330 may form a junction surface where the first substrate structure ST1 and the second substrate structure ST2 are joined. For example, in the cell area CA, the first junction insulation layer 330 may be joined to the second junction insulation layer 430 of the second substrate structure ST2, thereby forming a part of the junction surface of the first substrate structure ST1 and the second substrate structure ST2.

In the scribe lane area SLA, the first junction insulation layer 330 may include a recessed portion SP. The recessed portion SP may have a concave shape from the upper surface 330_U of the first junction insulation layer 330 toward the upper surface of the first substrate 310. That is, the recessed portion SP may be depressed in the third direction (the direction Z) from the upper surface 330_U of the first junction insulation layer 330. This may be due to a process characteristic resulting from an erosion phenomenon in which at least a portion of the first junction insulation layer 330 is removed together during the planarization process of the plurality of first dummy pads 360 and the plurality of first bonding pads 350 by performing a chemical mechanical polishing (CMP) process. The erosion phenomenon may occur more easily or often as the metal density increases. That is, in some example embodiments, since the first metal density of the scribe lane area SLA is greater than or equal to the second metal density of the cell area CA, at least a portion of the first junction insulation layer 330 in the scribe lane area SLA may be removed, thereby forming the recessed portion SP.

However, it is not limited thereto, in the scribe lane area SLA, a part of the first junction insulation layer 330 may be jointed to the second junction insulation layer 430 of the second substrate structure ST2 to form a part of the junction surface of the first substrate structure ST1 and the second substrate structure ST2, but is not limited thereto.

The first junction insulation layer 330 may include an insulating material. For example, the first junction insulation layer 330 may include silicon carbon nitride, but is not limited thereto. As another example, the first junction insulation layer 330 may include at least one of silicon oxide, silicon oxynitride, silicon carbon oxynitride, and silicon nitride.

Hereinafter, the second substrate structure ST2 is described.

The second substrate structure ST2 according to some example embodiments may include a second substrate 410, a plurality of second bonding pads 450 and a plurality of second dummy pads 460 positioned on the lower surface of the second substrate 410. Also, the second substrate structure ST2 according some example embodiments may further include a plurality of upper insulation layers 421, 422, and 423 sequentially positioned on the lower surface of the second substrate 410, an upper wire 472 positioned within the plurality of upper insulation layers 421, 422, and 423, a second junction insulation layer 430 positioned on the lower surface of the third upper insulation layer 423, a second bonding via 473 connected to the plurality of second bonding pads 450, and a second dummy via 465 connected to the plurality of second dummy pads 460.

In some example embodiments, the second substrate structure ST2 may have substantially the same or the same shape, structure, arrangement, and connection relationship as the first substrate structure ST1. The second substrate structure ST2 may have a symmetrical shape to the first substrate structure ST1 along the first direction (the direction X), but is not limited thereto.

The second junction insulation layer 430 may be positioned on the first junction insulation layer 330 of the first substrate structure ST1. The second junction insulation layer 430 may be positioned in the cell area CA and the scribe lane area SLA. The second junction insulation layer 430 may surround the plurality of second bonding pads 450 and the plurality of second dummy pads 460.

In some example embodiments, the second junction insulation layer 430 may form a junction surface with the first junction insulation layer 330. For example, in the cell area CA, the second junction insulation layer 430 may be joined to the first junction insulation layer 330 to form a portion of the junction surface of the first substrate structure ST1 and the second substrate structure ST2.

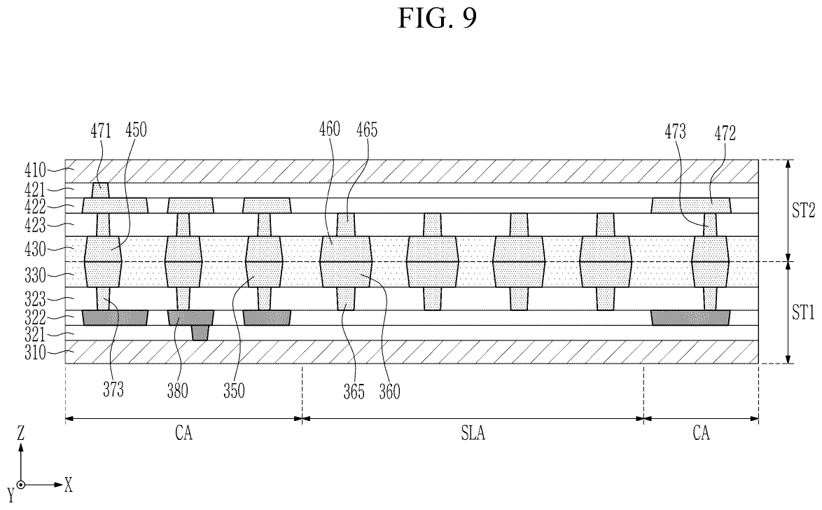

In the scribe lane area SLA, the second junction insulation layer 430 may be positioned spaced apart from the first junction insulation layer 330 in the third direction (the direction Z). For example, the second junction insulation layer 430 may include a depression concave toward the second substrate 410, similar to the first junction insulation layer 330, and the recessed portion of the second junction insulation layer 430 may overlap the recessed portion SP of the first junction insulation layer 330 in the third direction (the direction Z). Accordingly, in the scribe lane area SLA, the second junction insulation layer 430 may be positioned spaced apart from the first junction insulation layer 330 in the third direction (the direction Z). Accordingly, a void VD may be provided between the second junction insulation layer 430 and the first junction insulation layer 330. The void VD may be positioned between the first substrate structure ST1 and the second substrate structure ST2 in the scribe lane area SLA. Accordingly, even if at least a portion of the first junction insulation layer 330 and/or the second junction insulation layer 430 is not sufficiently polished, a sufficient margin may be secured by the void VD. However, it is not limited thereto, in the scribe lane area SLA, the second junction insulation layer 430 may form a junction surface with the first junction insulation layer 330. The description of this will be given later with reference to FIG. 9.

The second junction insulation layer 430 may include the same material as the first junction insulation layer 330. For example, the second junction insulation layer 430 may include silicon carbon nitride, but is not limited thereto. As another example, the second junction insulation layer 430 may include at least one of silicon oxide, silicon oxynitride, silicon carbon oxynitride, and silicon nitride. The remaining description of the second junction insulation layer 430 is substantially the same as the description of the first junction insulation layer 330, so it will be omitted.

The plurality of second bonding pads 450 may penetrate the second junction insulation layer 430. The plurality of second dummy pads 460 may refer to pads positioned in the cell area CA and penetrating the second junction insulation layer 430. In some example embodiments, the plurality of second bonding pads 450 may be positioned in the cell area CA. The plurality of second bonding pads 450 may overlap the plurality of first bonding pads 350 in the third direction (the direction Z). The plurality of second bonding pads 450 may be joined to the plurality of first bonding pads 350. The plurality of second bonding pads 450 may form a junction surface with the plurality of first bonding pads 350. For example, in the cell area CA, the plurality of second bonding pads 450 may be joined to the plurality of first bonding pads 350 to form a part of the junction surface of the first substrate structure ST1 and the second substrate structure ST2.

Additionally, the plurality of second dummy pads 460 may penetrate the second junction insulation layer 430. The plurality of second dummy pads 460 may mean pads positioned in the scribe lane area SLA and penetrating the second junction insulation layer 430. In some example embodiments, the plurality of second dummy pads 460 may be positioned in the scribe lane area SLA. The plurality of second dummy pads 460 may overlap the plurality of first dummy pads 360 in the third direction (the direction Z). At least a portion of the plurality of second dummy pads 460 may be jointed to the plurality of first dummy pads 360. The plurality of second dummy pads 460 may form a junction surface with the plurality of first dummy pads 360. Additionally, another part of the plurality of second dummy pads 460 may be positioned spaced apart from the plurality of first dummy pads 360 in the third direction (the direction Z). For example, another portion of the plurality of second dummy pads 460 may be positioned on the void VD provided between the recessed portion SP of the first junction insulation layer 330 and the recessed portion of the second junction insulation layer 430. In this case, the void VD may be positioned between another part of the plurality of second dummy pads 460 and the plurality of first dummy pads 360, and another part of the plurality of second dummy pads 460 may be positioned spaced apart from the plurality of first dummy pads 360 in the third direction (the direction Z).

In some example embodiments, the density of the plurality of second dummy pads 460 positioned in the scribe lane area SLA may be greater than or equal to the density of the plurality of second bonding pads 450 positioned in the cell area CA. That is, the sum of the areas of the plurality of second bonding pads 450 per a unit area on a plane may be less than or equal to the sum of the areas of the plurality of second dummy pads 460 per a unit area. For example, the diameter of the plurality of second dummy pads 460 positioned in the scribe lane area SLA may be greater than or equal to the diameter of the plurality of second bonding pads 450 positioned in the cell area CA. As another example, the spacing between the plurality of second dummy pads 460 positioned in the scribe lane area SLA may be less than or equal to the spacing between the plurality of second bonding pads 450 positioned in the cell area CA. The explanation for this is substantially the same as the explanation for the plurality of first bonding pads 350 and the plurality of first dummy pads 360 of the first substrate structure ST1, so it will be omitted.

The lower surface of the plurality of second dummy pads 460 may be positioned at a higher level than the lower surface of the plurality of second bonding pads 450. That is, the lower surface of the plurality of second dummy pads 460 may be positioned closer from the lower surface of the second substrate 410 than the lower surface of the plurality of second bonding pads 450. This may be due to a process characteristic in which the plurality of second dummy pads 460 are polished (for example, an excessive or over polishing) more than the plurality of second bonding pads 450. Accordingly, a second thickness TH2 may be generated from the lower surface of the plurality of second bonding pads 450 to the lower surface of the plurality of second dummy pads 460. The second thickness TH2 may be substantially the same or the same as the first thickness TH1, but is not limited thereto. In some example embodiments, a predetermined (or alternatively, desired or determined) space may be secured in the scribe lane area SLA as the first thickness TH1 is generated from the upper surface 350_U of the plurality of first bonding pads 350 to the upper surface 360_U of the plurality of first dummy pads 360 and the second thickness TH2 is generated from the lower surface of the plurality of second bonding pads 450 to the lower surface of the plurality of second dummy pads 460. Even if at least a portion of a plurality of first dummy pads 360 and/or a plurality of second dummy pads 460 is not sufficiently polished, a sufficient margin may be secured by the space.

The plurality of second bonding pads 450 and the plurality of second dummy pads 460 may include a conductive material. The plurality of second bonding pads 450 and the plurality of second dummy pads 460 may include the same material as the plurality of first bonding pads 350 and the plurality of first dummy pads 360. Additionally, the plurality of second bonding pads 450 may include the same material as the plurality of second dummy pads 460. For example, the plurality of second bonding pads 450 and the plurality of second dummy pads 460 may include copper (Cu), but is not limited thereto, and may also include a conductive material such as tungsten (W) or aluminum (Al).

The plurality of upper insulation layers 421, 422, and 423 may be disposed on the second junction insulation layer 430. For example, the third upper insulation layer 423 may be positioned on the second junction insulation layer 430, the second upper insulation layer 422 may be positioned on the third upper insulation layer 423, and the first upper insulation layer 421 may be positioned on the second upper insulation layer 422. The remaining description of the plurality of upper insulation layers 421, 422, and 423 is substantially the same as the description of the plurality of lower insulation layers 321, 322, and 323 of the first substrate structure ST1, so it will be omitted.

The upper wire 472 and the upper via 471 may be positioned within the plurality of upper insulation layers 421, 422, and 423. For example, the upper wire 472 may be positioned above the third upper insulation layer 423. The upper wire 472 may penetrate the second upper insulation layer 422. The upper wire 472 may be positioned in the cell area CA and electrically connected to the plurality of second bonding pads 450. The upper wire 472 may not be positioned in the scribe lane area SLA. The upper wire 472 may be electrically floating from the plurality of second dummy pads 460. The upper via 471 may be positioned above the second upper insulation layer 422. The upper via 471 may pass through the first upper insulation layer 421 and be electrically connected to the upper wire 472.

The second substrate 410 may be a semiconductor substrate, such as a semiconductor wafer (W in FIG. 1). The second substrate 410 may be a bulk silicon substrate, a silicon-on-insulator (SOI) substrate, a germanium (Ge) substrate, a germanium-on-insulator (GOI) substrate, a silicon-germanium (Si—Ge) substrate, or a substrate of an epitaxial thin film obtained by performing selective epitaxial growth (SEG).

According to some example embodiments, the first substrate structure ST1 and the second substrate structure ST2 of the semiconductor device may be a semiconductor device joined by a C2C (Cu to Cu) wafer bonding method. The first substrate structure ST1 and the second substrate structure ST2 may be a semiconductor device joined by a hybrid copper bonding (HCB) method.

At this time, in the cell area CA, the plurality of first bonding pads 350 and the plurality of second bonding pads 450 may be joined to form a part of the junction surface of the first substrate structure ST1 and the second substrate structure ST2. Meanwhile, in the scribe lane area SLA, the plurality of first dummy pads 360 and the plurality of second dummy pads 460 may be positioned. At this time, the first metal density of the scribe lane area SLA may be greater than or equal to the second metal density of the cell area CA. That is, the sum of the areas of the plurality of first dummy pads 360 of the scribe lane area SLA per a unit area on a plane may be greater than or equal to the sum of the areas of the plurality of first bonding pads 350 of the cell area CA per a unit area. Accordingly, the polishing amount of the scribe lane area SLA with the high metal density may be greater than that of the cell area CA, and the upper surface 360_U of the plurality of first dummy pads 360 may be positioned at a lower level than the upper surface 350_U of the plurality of first bonding pads 350. Therefore, the sufficient space may be secured in the scribe lane area SLA to allow for the steps such as the protruding portion EP to be disposed in at least some of the plurality of first dummy pads 360. Accordingly, the first substrate structure ST1 and the second substrate structure ST2 may be joined (e.g., easily) without the spacing in the cell area CA, and the hybrid bonding quality of the semiconductor device according to some example embodiments may be improved.

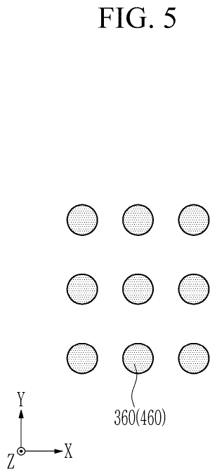

Hereinafter, the planar shapes of the plurality of first dummy pads 360 and the plurality of second dummy pads 460 of the semiconductor device according to some example embodiments will be described with reference to FIG. 5 to FIG. 7.

FIG. 5 to FIG. 7 are top plan views illustrating a plurality of first dummy pads of a semiconductor device according to some example embodiments.

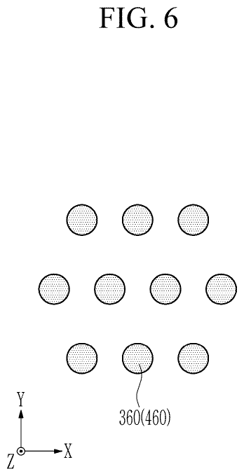

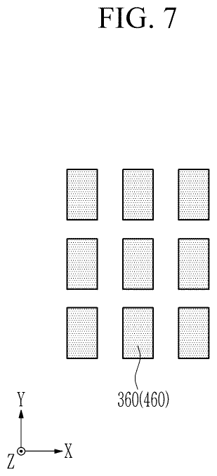

Referring to FIG. 5 to FIG. 7, the plurality of first dummy pads 360 and the plurality of second dummy pads 460 may have various shapes in a plane. For example, as illustrated in FIG. 5 and FIG. 6, the plurality of first dummy pads 360 and the plurality of second dummy pads 460 may have a circular shape. At this time, the plurality of first dummy pads 360 and the plurality of second dummy pads 460 may be arranged spaced apart from each other along the first direction (the direction X) and the second direction (the direction Y). Alternatively, the plurality of first dummy pads 360 and the plurality of second dummy pads 460 may be arranged spaced apart from each other along a first diagonal direction intersecting the first direction (the direction X) and the second direction (the direction Y) and along a second diagonal direction intersecting the first direction (the direction X), the second direction (the direction Y), and the first diagonal direction. That is, as in some example embodiments of FIG. 6, the plurality of first dummy pads 360 and the plurality of second dummy pads 460 may be arranged in a honey comb shape. As another example, as illustrated in FIG. 7, the plurality of first dummy pads 360 and the plurality of second dummy pads 460 may be a quadrangle shape. At this time, the lengths of the plurality of first dummy pads 360 and the plurality of second dummy pads 460 along the first direction (the direction X) may be different from or may be the same as the lengths of the plurality of first dummy pads 360 and the plurality of second dummy pads 460 along the second direction (the direction Y). However, it is not limited thereto, the plurality of first dummy pads 360 and the plurality of second dummy pads 460 may be, for example, oval shapes or polygon shapes, and may be in a pattern shown above or another pattern.

Below, semiconductor devices according to some example embodiments are described with further reference to FIG. 8 to FIG. 11.

FIG. 8 to FIG. 11 are cross-sectional views showing a cell area and a scribe lane area of a semiconductor device according to some example embodiments.

The semiconductor device according to some example embodiments illustrated in FIG. 8 to FIG. 11 has many parts identical to the semiconductor device according to some example embodiments illustrated in FIG. 2 to FIG. 4, so the description thereof will be omitted and the differences will be mainly explained. Additionally, the same reference numerals are used for the same components as in the previous embodiment.

As described above in FIG. 2 to FIG. 4, the first metal density of the scribe lane area SLA may be greater than or equal to the second metal density of the cell area CA.

Referring to FIG. 8, in some example embodiments of the semiconductor device, a first interval P1 of the plurality of first dummy pads 360 positioned in the scribe lane area SLA may be smaller than a second interval P2 of the plurality of first bonding pads 350 positioned in the cell area CA. At this time, the first width D1 of the plurality of first dummy pads 360 positioned in the scribe lane area SLA may be greater than or equal to the second width D2 of the plurality of first bonding pads 350 positioned in the cell area CA, but is not limited thereto. For example, the first width D1 of the plurality of first dummy pads 360 positioned in the scribe lane area SLA may be smaller than the second width D2 of the plurality of first bonding pads 350 positioned in the cell area CA. Even in this case, the sum of the areas of the plurality of first dummy pads 360 of the scribe lane area SLA per a unit area on a plane may be greater than or equal to the sum of the areas of the plurality of first bonding pads 350 of the cell area CA per a unit area. Additionally, it goes without saying that the spacing of the plurality of second dummy pads 460 positioned in the scribe lane area SLA may be smaller than the spacing of the plurality of second bonding pads 450 positioned in the cell area CA.

Referring to FIG. 9, in some example embodiments of the semiconductor device, the plurality of first dummy pads 360 may be jointed to the plurality of second dummy pads 460. That is, in the scribe lane area SLA, the plurality of first dummy pads 360 and the plurality of second dummy pads 460 may come into contact with each other. At this time, the plurality of first dummy pads 360 and the plurality of second dummy pads 460 may form a junction surface, and form a part of a junction surface of the first substrate structure ST1 and the second substrate structure ST2.

Additionally, in the scribe lane area SLA, a void (VD in FIG. 3) may not be provided between the first junction insulation layer 330 and the second junction insulation layer 430. That is, in the scribe lane area SLA, the first junction insulation layer 330 and the second junction insulation layer 430 may form a junction surface, and form a part of the junction surface of the first substrate structure ST1 and the second substrate structure ST2.

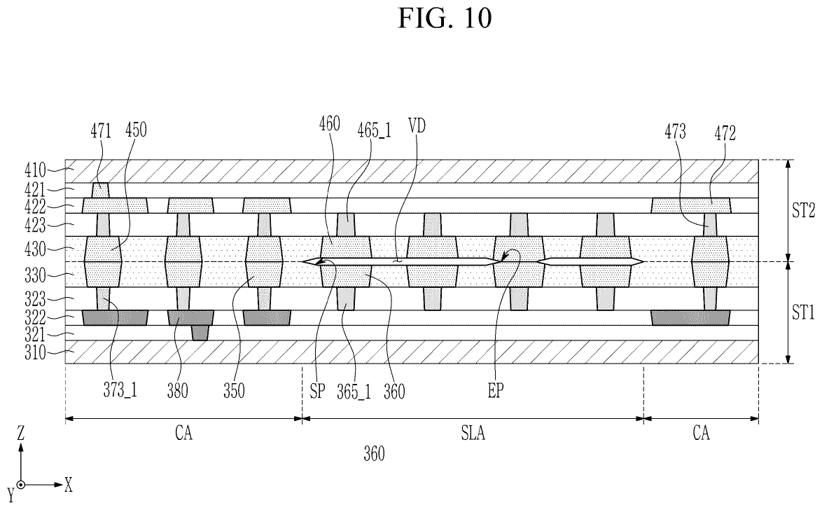

Referring to FIG. 10, in some example embodiments a boundary may be recognized between the first bonding via 373_1 and the plurality of first bonding pads 350 of the semiconductor device. The first bonding via 373_1 may include a different material from the plurality of first bonding pads 350, but is not limited thereto. Additionally, a boundary may be recognized between the first dummy via 365_1 and the plurality of first dummy pads 360. The first dummy via 365_1 may include a different materials than the plurality of first dummy pads 360, but is not limited thereto. This may be due to the process characteristic that the first bonding via 373_1 is formed in a different process from the plurality of first bonding pads 350. Additionally, it may be due to the process characteristic that the first dummy via 365_1 is formed in a different process from the plurality of first dummy pads 360.

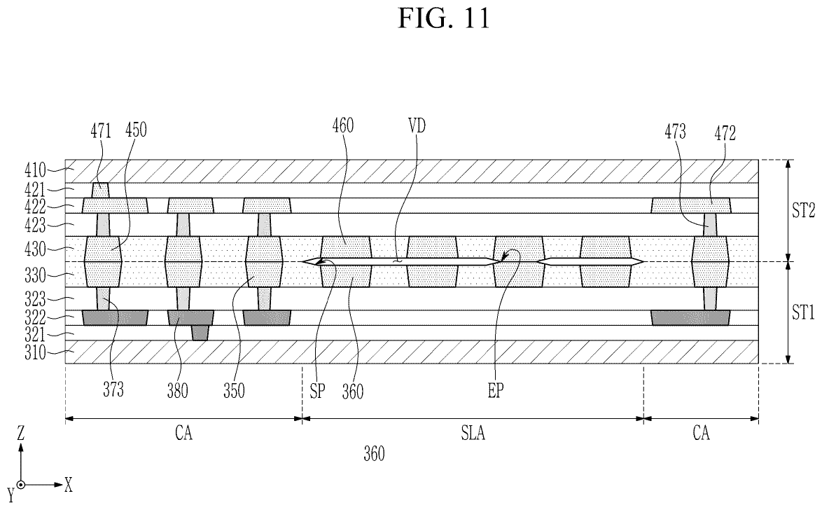

Referring to FIG. 11, the semiconductor device according to some example embodiments may not include a first dummy via 365. That is, the plurality of first dummy pads 360 may be positioned on the third lower insulation layer 323. The lower surface of the plurality of first dummy pads 360 may be in contact with the third lower insulation layer 323. The entire lower surface of the plurality of first dummy pads 360 may be in contact with the second lower insulation layer 322. Each of the plurality of first dummy pads 360 may be electrically floating. At this time, the first bonding via 373 may be positioned between the plurality of first bonding pads 350 and the lower wire 380.

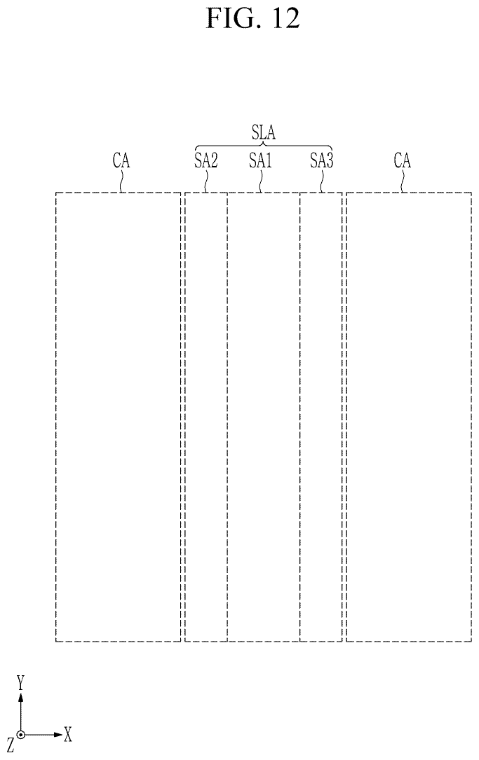

Hereinafter, semiconductor devices according to some example embodiments are described with reference to FIG. 12 to FIG. 16.

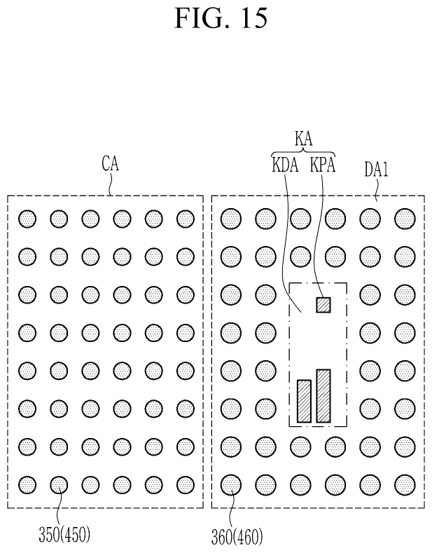

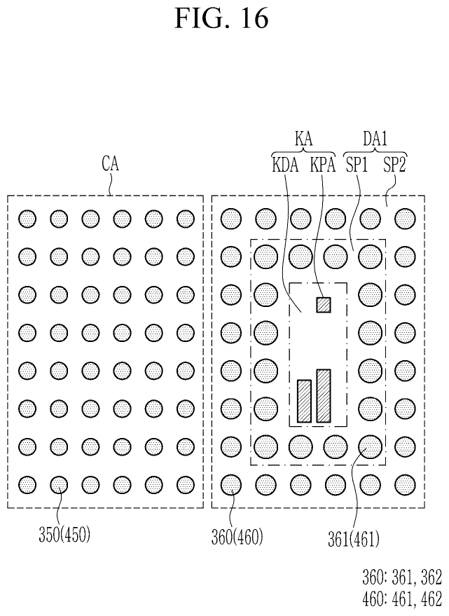

FIG. 12 to FIG. 14 are top plan views showing a cell area and a scribe lane area of a semiconductor device according to some example embodiments. FIG. 15 and FIG. 16 are top plan views showing a cell area, a key area, and a first division area of a semiconductor device according to some example embodiments.

The semiconductor device according to some example embodiments illustrated in FIG. 12 to FIG. 16 has many parts identical to the semiconductor device according to some example embodiments illustrated in FIG. 2 to FIG. 4, so the description thereof will be omitted and the differences will be mainly explained. Additionally, the same reference numerals are used for the same components as in the previous embodiment.

Referring to FIG. 12, the scribe lane area SLA of the semiconductor device according to some example embodiments may include a plurality of areas SA1, SA2, and SA3 having different metal densities.

For example, the scribe lane area SLA of the semiconductor device according to some example embodiments may include a first area SA1 positioned spaced apart from the cell area CA, and a second area SA2 and a third area SA3 positioned between the first area SA1 and the cell area CA.

The first area SA1 to the third area SA3 may be extended in the second direction (the direction Y), but is not limited thereto. The second area SA2 and the third area SA3 may surround the cell area CA. A plurality of first dummy pads 360 may be positioned within the first area SA1 to the third area SA3.

In some example embodiments, the metal density of the first area SA1 to third area SA3 may be greater than or equal to the second metal density of the cell area CA. That is, the sum of the areas of the plurality of first dummy pads 360 of the first area SA1 per a unit area on a plane may be greater than or equal to the sum of the areas of the plurality of first bonding pads 350 of the cell area CA per a unit area. Additionally, the sum of the areas of the plurality of first dummy pads 360 of the second area SA2 per a unit area on a plane may be greater than or equal to the sum of the areas of the plurality of first bonding pads 350 of the cell area CA per a unit area. Additionally, the sum of the areas of the plurality of first dummy pads 360 of the third area SA3 per a unit area on a plane may be greater than or equal to the sum of the areas of the plurality of first bonding pads 350 of the cell area CA per a unit area.

In some example embodiments, the first area SA1 to the third area SA3 may have different metal densities. The metal density of the first area SA1 may be greater than the metal density of the second area SA2 and the metal density of the third area SA3. That is, the sum of the areas of the plurality of first dummy pads 360 of the first area SA1 per a unit area on a plane may be greater than the sum of the areas of the plurality of first dummy pads 360 of the second area SA2 per a unit area on a plane. Additionally, the sum of the areas of the plurality of first dummy pads 360 of the first area SA1 per a unit area on a plane may be greater than the sum of the areas of a plurality of first dummy pads 360 of the third area SA3 per a unit area on a plane. For example, as the width of the plurality of first dummy pads 360 of the scribe lane area SLA per a unit area increases, the first metal density may increase. That is, the metal density of the scribe lane area SLA may increase as it moves away from the cell area CA.

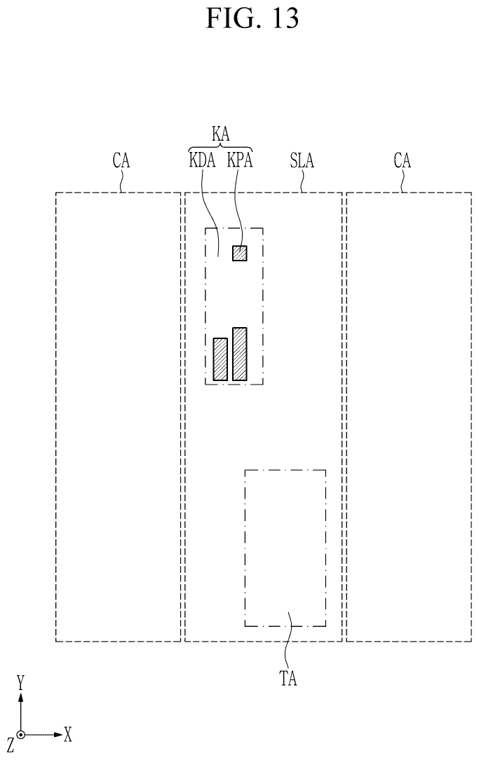

Referring to FIG. 13, the scribe lane area SLA of the semiconductor device according to some example embodiments may include a key area KA and a test element area TA.

The key area KA may be an area where a key pattern for an alignment of the semiconductor device is positioned. In some example embodiments, the key area KA may include a key pattern area KPA where the key pattern is positioned and a key dummy area KDA surrounding the key pattern area KPA.

In the key pattern area KPA, the key patterns may be positioned. The key patterns may be sort keys such as global sort keys, local sort keys, registration sort keys, orthogonality sort keys, overlay sort keys, and measurement keys, and monitoring patterns for monitoring processes, but is not limited thereto. In some example embodiments, the metal density of the key pattern area KPA may be less than the metal density of the cell area CA.

The key dummy area KDA may surround the key pattern area KPA, and the key dummy area KDA may be an area for smoothly recognizing the key pattern positioned in the key pattern area KPA. A conductive material may be not positioned such as the plurality of first dummy pads 360 in the key dummy area KDA. The metal density of the key dummy area KDA may be less than the metal density of the cell area CA. For example, the metal density of the key dummy area KDA may be about or exactly 0%. Even in such cases, the average metal density of the entire scribe lane area SLA may be greater than or equal to the metal density of the cell area CA.

The test element area TA may be positioned apart from the cell area CA. The test element area TA may position wirings that determine whether the semiconductor devices are operating normally. The metal density of the test element area TA may be less than the metal density of the cell area CA, but is not limited thereto. Even in such cases, the average metal density of the entire scribe lane area SLA may be greater than or equal to the metal density of the cell area CA.

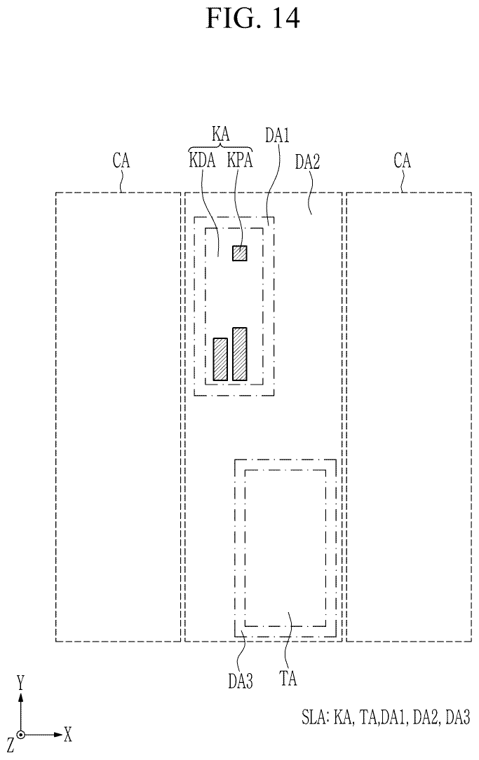

Referring further to FIG. 14 and FIG. 15, the scribe lane area SLA of the semiconductor device according to some example embodiments may include a first division area DA1 surrounding the key area KA and a second division area DA2 positioned between the first division area DA1 and the cell area CA. Like some example embodiments of FIG. 2 to FIG. 4, a plurality of first dummy pads 360 may be positioned in the first division area DA1 and the second division area DA2.

The first division area DA1 may surround the key area KA. The first division area DA1 may surround the key dummy area KDA and be positioned apart from the key pattern area KPA.

In some example embodiments, the metal density of the first division area DA1 may be greater than or equal to the metal density of the cell area CA. That is, the sum of the areas of the plurality of first dummy pads 360 of the first division area DA1 per a unit area on a plane may be greater than the sum of the areas of the plurality of first bonding pads 350 of the cell area CA per a unit area on a plane. For example, as illustrated in FIG. 15, the width of the plurality of first dummy pads 360 of the first division area DA1 may be greater than the width of the plurality of first bonding pads 350 of the cell area CA. However, it is not limited thereto, as in some example embodiments of FIG. 8, the spacing between the plurality of first dummy pads 360 of the first division area DA1 may be smaller than the spacing between the plurality of first bonding pads 350 of the cell area CA.

Additionally, the metal density of the first division area DA1 may be greater than the metal density of the key area KA. For example, the metal density of the first division area DA1 may be greater than the metal density of the key pattern area KPA and be greater than the metal density of the key dummy area KDA.

Additionally, the sum of the areas of the plurality of first dummy pads 360 of the second division area DA2 per a unit area on a plane may be greater than the sum of the areas of the plurality of first bonding pads 350 of the cell area CA per a unit area on a plane.

In some example embodiments, the metal density of the first division area DA1 may be greater than the metal density of the second division area DA2. That is, the sum of the areas of the plurality of first dummy pads 360 of the first division area DA1 per a unit area on a plane may be greater than the sum of the areas of the plurality of first dummy pads 360 of the second division area DA2 per a unit area on a plane. For example, the width of the plurality of first dummy pads 360 in the first division area DA1 may be greater than the width of the plurality of first dummy pads 360 in the second division area DA2. As another example, the interval between the plurality of first dummy pads 360 in the first division area DA1 may be smaller than the interval between the plurality of first dummy pads 360 in the second division area DA2.

Accordingly, even if the metal density of the key area KA is smaller than the second metal density of the key area CA, as described in some example embodiments of FIG. 13, the metal density of the first division area DA1 surrounding the key area KA may be greater than the metal density of the remaining areas (e.g., the second division area DA2) of the scribe lane area SLA. Therefore, in the process of planarizing the upper surface of the scribe lane area SLA, the patterns and/or the plurality of first dummy pads 360 around the key area KA may be polished to the sufficient depth. Accordingly, when the first substrate structure ST1 and the second substrate structure ST2 are joined, the joining may be more easily done without the gap occurring between the first substrate structure ST1 and the second substrate structure ST2. In some example embodiments, the average of the metal density of the first division area DA1 and the metal density of the key area KA may be greater than or equal to the second metal density of the key area CA, but is not limited thereto. However, but is not limited thereto, the metal density of the first division area DA1 may be less than or equal to the metal density of the second division area DA2. In some example embodiments, the average metal density of the entire scribe lane area SLA may be greater than or equal to the metal density of the cell area CA.

In some example embodiments, the scribe lane area SLA may further include a third division area DA3 surrounding the test element area TA. In the third division area DA3, a plurality of first dummy pads 360 may be positioned.

The third division area DA3 may surround the test element area TA. In some example embodiments, the metal density of the third division area DA3 may be greater than or equal to the metal density of the cell area CA. Also, the metal density of the third division area DA3 may be greater than the metal density of the second division area DA2, but is not limited thereto.

Referring further to FIG. 16, the first division area DA1 of the semiconductor device according to some example embodiments may include a plurality of portions SP1 and SP2 having different metal densities.

For example, the first division area DA1 may include a first portion SP1 surrounding the key area KA and a second portion SP2 surrounding the first portion SP1. At this time, the metal density of the first portion SP1 may be greater than the metal density of the second portion SP2. That is, the sum of the areas of the plurality of first dummy pads 361 of the first portion SP1 per a unit area on a plane may be greater than the sum of the areas of the plurality of first dummy pads 362 of the second portion SP2 per a unit area on a plane. For example, the width of the plurality of first dummy pads 361 of the first portion SP1 may be greater than the width of the plurality of first dummy pads 362 of the second portion SP2. As another example, the interval between the plurality of first dummy pads 361 of the first portion SP1 may be smaller than the interval between the plurality of first dummy pads 362 of the second portion SP2.

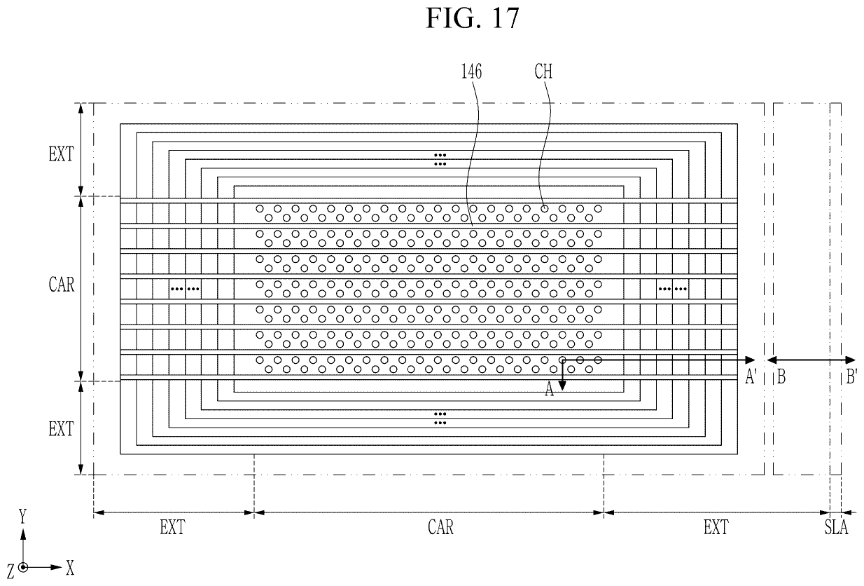

Hereinafter, the semiconductor device according to some example embodiments is described in detail with reference to FIG. 17 to FIG. 20.

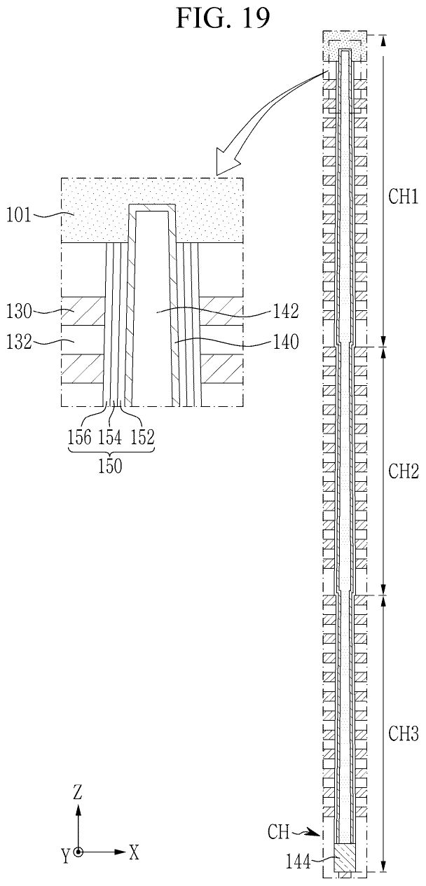

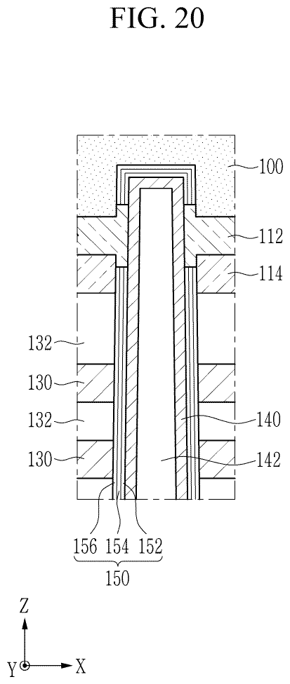

FIG. 17 is a cross-sectional view schematically illustrating a semiconductor device according to some example embodiments. FIG. 18 is a cross-sectional view illustrating a channel structure of a semiconductor device according to some example embodiments. FIG. 19 and FIG. 20 are cross-sectional views illustrating a channel structure of a semiconductor device according to some example embodiments.

In some example embodiments of FIG. 17 to FIG. 20, the junction structure of the first substrate structure ST1 and the second substrate structure ST2 of FIG. 1 to FIG. 16 may be applied.

First, the semiconductor device according to some example embodiments of FIG. 17 and referring to FIG. 18 may include a cell structure CELL having a memory cell structure, and a peripheral structure PERI having a peripheral circuit structure that controls the operation of the memory cell structure. At this time, the cell structure CELL and the peripheral structure PERI may be a semiconductor device joined by a C2C (Cu to Cu) wafer bonding method. In some example embodiments, the cell structure CELL and the peripheral structure PERI may be the semiconductor device joined by a hybrid copper bonding (HCB) method according to some example embodiments of FIG. 2 to FIG. 16. For example, the peripheral structure PERI and the cell structure CELL may be parts corresponding to the first structure 1100F and the second structure 1100S of the semiconductor device 1100 included in the electron system 1000 illustrated in FIG. 21, respectively.

Here, the peripheral structure PERI may include a peripheral circuit structure formed on the first cell substrate 200, and the cell structure CELL may include a gate stacking structure 120 and a channel structure CH formed on the cell area CR as a memory cell structure.

In some example embodiments, the peripheral structure PERI may correspond to the first substrate structure ST1 of some example embodiments of FIG. 1 to FIG. 16, and the cell structure CELL may correspond to the second substrate structure ST2 of some example embodiments of FIG. 1 to FIG. 16. That is, the structure of the peripheral structure PERI and the cell structure CELL joined by the C2C (Cu to Cu) wafer bonding method may be substantially the same as the junction structure of the first substrate structure ST1 and the second substrate structure ST2.

The semiconductor device according to some example embodiments may include a cell array area CAR and an extension area EXT.

The memory cell array including the plurality of memory cells may be formed on the cell array area CAR. For example, a channel structure CH, a plurality of gate electrodes 130, and a bit line BL, which will be described later, may be positioned on the cell array area CAR. In the following description, the surface of the second cell substrate 100 on which the memory cell array is arranged may be referred to as one surface or a front side. Conversely, the surface of the second cell substrate 100 opposite to the front side of the second cell substrate 100 may be referred to as a back side or the other side of the second cell substrate 100. That is, one surface of the second cell substrate 100 may be a surface facing the peripheral structure PERI, and the other surface of the second cell substrate 100 may be a surface facing one surface of the second cell substrate 100.

The extension area EXT may be defined around the cell array area CAR. For example, the extension area EXT may surround the cell array area CAR from a plane perspective. In the extension area EXT, a structure or wiring for connecting the gate stacking structure 120 and/or the channel structure CH positioned in the cell array area CAR to the peripheral structure PERI or the external circuit may be positioned. Additionally, in the extension area EXT, a source contact 186 and an input/output contact 188, which will be described later, may be positioned.

According to some example embodiments, the cell structure CELL may include a second cell substrate 100, a gate stacking structure 120, a channel structure CH, a channel pad 144, a separation structure 146, a cell wiring part 180, and a second insulating structure 300.

The second cell substrate 100 may include a common source plate 101 and an insulating pattern 102. The common source plate 101 may be provided to the parts of the cell area CR and the extension area EXT. The common source plate 101 may be connected to the channel structure CH and the source contact 186. For example, the common source plate 101 may be connected to the channel layer 140 of the channel structure CH in the cell array area CAR. The common source plate 101 may be connected to the source contact 186 in the extension area EXT. This common source plate 101 may be provided as a common source line of a non-volatile memory device (e.g., CSL of FIG. 21). The common source plate 101 may include, for example, a polycrystalline silicon doped with an impurity or a metal, but is not limited thereto.

The insulating pattern 102 may be provided in a part of the extension area EXT. The insulating pattern 102 may not be provided on the cell array area CAR. The insulating pattern 102 may be positioned around the common source plate 101. The insulating pattern 102 may include, for example, at least one of silicon oxide, silicon nitride, silicon oxynitride, and silicon carbide, but is not limited thereto.

The gate stacking structure 120 may be positioned on the front surface of the second cell substrate 100. The gate stacking structure 120 may include a plurality of cell insulation layers 132 and a plurality of gate electrodes 130 that are alternately stacked.

The cell insulation layer 132 may include an interlayer insulating layer 132m positioned between two adjacent gate electrodes 130 within the gate stacking structure 120, and a pad insulating part 132i positioned at the bottom of the gate stacking structure 120. Additionally, the cell insulation layer 132 may include a plurality of lower cell insulation layers 132a, 132b, and 132c covering the lower surface of each of the plurality of gate stacking structures 120a, 120b, and 120c. For simplicity, FIG. 18 illustrates an example in which the cell insulation layer 132 is formed as a single unit without a boundary in the extension area EXT. However, the cell insulation layer 132 positioned in the extension area EXT may have various structures including one or a plurality of insulation layers, and some example embodiments is not limited thereto.

In some example embodiments, the gate electrode 130 and the interlayer insulating layer 132m of the gate stacking structure 120 may extend in the first direction (the direction X) and/or the second direction (the direction Y). For example, in the direction away from the cell array area CAR, the length of the plurality of gate electrodes 130 may include a step shape that sequentially increases toward the second cell substrate 100. At this time, the plurality of gate electrodes 130 may include a portion having a step shape in one direction or a plurality of directions. Accordingly, some of the gate electrode 130 may be extended to different lengths and have a step, and the lower surface of each of the gate electrodes 130 may include a pad portion PP in contact with the pad insulating part 132i. The pad portion PP may mean an area where the gate contact 184 and the gate electrode 130 come into contact.

The height of the gate electrode 130 in contact with the gate contact 184 in the pad portion PP along the third direction (the direction Z) may be higher than the height of the other gate electrode 130 along the third direction (the direction Z). Here, the third direction (the direction Z) may be a direction perpendicular to the front surface of the second cell substrate 100. Due to this, the contact area between the gate contact 184 and the gate electrode 130 may be increased, but is not limited thereto.

The gate electrode 130 may include a variety of conductive materials. For example, the gate electrode 130 may include a metallic material such as tungsten (W), copper (Cu), aluminum (Al), polycrystalline silicon, a metal nitride (e.g., titanium nitride (TiN), tantalum nitride (TaN)), or a combination thereof. In some example embodiments, an insulating material may be further positioned outside the gate electrode 130. The cell insulation layer 132 may include various insulating materials. For example, the cell insulation layer 132 may include silicon oxide, silicon nitride, silicon oxynitride, a low dielectric constant material having a lower permittivity than silicon oxide, or a combination thereof.

The channel structure CH may be positioned within the gate stacking structure 120 of the cell array area CAR. The channel structure CH may penetrate the gate stacking structure 120 and extend in a cross direction (e.g., the third direction (the direction Z)) intersecting (e.g., vertically) the second cell substrate 100. The channel structure CH may have a columnar shape. For example, the channel structure CH may have a slanted side so that the width becomes narrower as it approaches the second cell substrate 100 according to an aspect ratio when viewed in a cross-section. However, some example embodiments are not limited to this, and the structure, shape, etc. of the channel structure CH may be modified in various ways.

Each channel structure CH forms a memory cell string, and the plurality of channel structures CH may be positioned spaced apart from each other on a plane while forming rows and columns. For example, on a plane, the plurality of channel structures CH may be positioned in various shapes, such as a lattice shape or a zigzag shape. However, some example embodiments are not limited to this, and the arrangement, shape, etc. of the channel structure CH may be modified in various ways.

Referring further to FIG. 19, the channel structure CH may include a channel layer 140 and a gate dielectric layer 150 positioned over the channel layer 140 between the gate electrode 130 and the channel layer 140. The channel structure CH may further include a core insulation layer 142 positioned inside (e.g., in the central area) of the channel layer 140, but as another example, the core insulation layer 142 may not be provided.

The gate dielectric layer 150 may include a tunneling layer 152, a charge storing layer 154, and a blocking layer 156 that are sequentially formed on the channel layer 140. In some example embodiments, the channel structure CH may further include a channel pad 144 connected to the channel layer 140.

The channel layer 140 may include a semiconductor material, for example, polycrystalline silicon. The core insulation layer 142 may include various insulating materials. For example, the core insulation layer 142 may include silicon oxide, silicon nitride, silicon oxynitride, or a combination thereof. The tunneling layer 152 may include an insulating material capable of tunneling charges. For example, the tunneling layer 152 may include silicon oxide, silicon oxynitride, etc. The storing layer 154 is used as a data storage area and may include polycrystalline silicon, silicon nitride, etc. The blocking layer 156 may include an insulating material that may prevent or reduce undesirable inflow of charge into the gate electrode 130. For example, the blocking layer 156 may include silicon oxide, silicon nitride, silicon oxynitride, a high dielectric constant material having a permittivity higher than silicon oxide or a combination thereof. However, the material, stacking structure, etc. of the channel layer 140, the core insulation layer 142, and the gate dielectric layer 150 may be modified in various ways, and some example embodiments are not limited thereto.

In some example embodiments, as illustrated in FIG. 19, the channel structure CH may include a portion that protrudes toward the back surface of the second cell substrate 100 from one surface of the gate stacking structure 120. That is, one end of the channel structure CH may be positioned between the front and rear sides of the common source plate 101. At this time, a part of the gate dielectric layer 150 positioned at one end of the channel structure CH may be removed. The upper surface of the gate dielectric layer 150 may be in contact with the lower surface of the common source plate 101. The channel layer 140 may be connected to the common source plate 101 on the cell array area CAR. The upper surface of the channel layer 140 may be positioned between the front and back sides of the second cell substrate 100. That is, a portion of the channel layer 140 may be provided within the common source plate 101. A portion of the upper surface and side surface of the channel layer 140 may be in contact with the common source plate 101.

However, it is not limited thereto, and as illustrated in FIG. 20, the cell array area CAR may further include horizontal conductive layers 112 and 114 positioned between the second cell substrate 100 and the gate stacking structure 120, and the channel layer 140 may be connected to the horizontal conductive layers 112 and 114. At this time, the horizontal conductive layers 112 and 114 may be connected to the channel structure CH and function as a common source line.

The channel pad 144 may be connected on the lower surface of the channel structure CH. The channel pad 144 may be positioned, for example, so that the channel pad 144 may be positioned on the lower surface of core insulation layer 142 and connected to channel layer 140. The channel pad 144 may include a conductive material, for example, impurity-doped polycrystalline silicon, but is not limited thereto.

In some example embodiments, the gate stacking structure 120 may include a plurality of gate stacking structures 120a, 120b, and 120c sequentially stacked on the lower surface of the second cell substrate 100, and the channel structure CH may include a plurality of channel structures CH1, CH2, and CH3 penetrating the plurality of gate stacking structures 120a, 120b, and 120c. Then, the number of the stacked gate electrodes 130 may be increased, thereby increasing the number of the memory cells with a stable structure. The drawing shows an example of three gate stacking structures 120, but some example embodiments are not limited thereto. Therefore, the gate stacking structure 120 may consist of one or two gate stacking structures, or may include four or more gate stacking structures. Additionally, the plurality of channel structures CH1, CH2, and CH3 constituting one channel structure CH may have a form connected to each other.

In some example embodiments, the separation structure 146 may penetrate the gate stacking structure 120. The separation structure 146 may extend in a direction (e.g., the third direction (the direction Z)) that intersects (e.g., vertically) the second cell substrate 100. Accordingly, the gate stacking structure 120 may be partitioned into multiple parts on a plane by the separation structure 146.

The separation structure 146 or the upper separation area may be filled with various insulating materials. For example, the separation structure 146 or the upper separation area may include an insulating material such as silicon oxide, silicon nitride, or silicon oxynitride. As another example, separation structure 146 may further include semiconductor material, metallic material, etc. In this case, the separation structure 146 may include a spacer layer including an insulating material, and a portion formed on the spacer layer and including a semiconductor material, a metallic material, etc. However, some example embodiments are not limited to this, and the structure, shape, material, etc. of the separation structure 146 or the upper separation area may be modified in various ways.

The cell structure CELL may be provided with a cell wiring part 180 to connect the gate stacking structure 120 and/or the channel structure CH provided in the cell array area CAR to the peripheral structure PERI or an external circuit.

Here, the cell wiring part 180 may include all members that electrically connect the gate electrode 130, the channel structure CH, etc. to the peripheral structure PERI or the external circuit. For example, the cell wiring part 180 may include the bit line BL, the gate contact 184, an input/output pad IO_PAD, an input/output contact 188, and a contact via 180a connected to each of these. According to some example embodiments, it may further include a connection wiring 190 connected to the bit line BL, the gate contact 184 and/or the input/output contact 188.

Specifically, the bit line BL may be positioned on the lower surface of the cell insulation layer 132 of the gate stacking structure 120 positioned in the cell array area CAR. The bit line BL may be extended in a direction intersecting the direction in which the gate electrode 130 extends. The bit line BL may be electrically connected to the channel structure CH (e.g., the channel pad 144) through the contact via 180a.

A member for the connection between the gate electrode 130 and the peripheral structure PERI may be provided in the extension area EXT.

Specifically, the gate contact 184 may be provided in the extension area EXT. The gate contact 184 may extend in the third direction (the direction Z) in the extension area EXT and penetrate the cell insulation layer 132 and the mold structure MS. The gate contact 184 may be connected to any one of the plurality of gate electrodes 130 stacked in a stepwise manner in the extension area EXT. For example, the gate contact 184 may be in contact with the side wall of the connecting gate electrode 130c including the pad portion PP. At this time, the pad portion PP of the connecting gate electrode 130c may come into contact with the pad insulating part 132i. In FIG. 18, the number of the gate contacts 184 is shown as eight for better understanding and ease of description, but is not limited thereto.

In some example embodiments, the upper surface of the gate contact 184 may be positioned within the insulating pattern 102. That is, the upper surface of the gate contact 184 may be provided between the front and rear surfaces of the insulating pattern 102. The gate contact 184 may not completely penetrate the second cell substrate 100. The gate contact 184 may include a conductive material. The gate contact 184 may include a metal such as, copper (Cu), tungsten (W), cobalt (Co), nickel (Ni), etc. but it is not limited thereto.

The insulating ring 184i may be interposed between the gate contact 184 and each of the plurality of gate electrodes 130. The insulating ring 184i may electrically isolate other gate electrodes except the gate electrode 130 including the pad portion PP from the gate contact 184. For example, the insulating ring 184i may prevent or reduce the remaining gate electrodes, except for the connecting gate electrode 130c that is connected to the gate contact 184, from contacting the gate contact 184. The insulating ring 184i may be a cyclic structure surrounding the gate contact 184. The insulating ring 184i may include an insulating material.

In the extension area EXT, the source contact 186 may be electrically connected to the common source plate 101. The source contact 186 may be electrically connected to the bit line BL via the connecting wiring 190. The connection wiring 190 may include a conductive material. The connecting wiring 190 may include, for example, tungsten (W) or copper (Cu), but is not limited thereto.

The input/output contact 188 may be connected to the input/output pad IO_PAD, which will be described later, through the cell insulation layer 132 in the extension area EXT. In some example embodiments, the common source plate 101 may not be positioned in the area where the input/output contact 188 is positioned. In the area where the input/output contact 188 is placed, the insulating pattern 102 may be positioned. The input/output contact 188 may be electrically connected to bit line BL via connection wiring 190.

The semiconductor device according to some example embodiments may further include a first upper insulation layer 103, a second upper insulation layer 104, an input/output pad IO_PAD, a cell pad C_PAD, an input/output via IO_VA, and a cell via C_VA.

The input/output pad IO_PAD may be provided on the second upper insulation layer 104 of the extension area EXT. The input/output pad IO_PAD may be electrically connected to the peripheral structure PERI through the input/output contact 188 and the input/output via IO_VA. Additionally, the input/output pad IO_PAD may electrically connect the external device and the semiconductor device to each other. The input/output pad IO_PAD may include a conductive material.

The cell pad C_PAD may be provided on the second upper insulation layer 104 of the cell array area CAR. The cell pad C_PAD may be electrically connected to the common source plate 101 through the cell via C_VA. The cell pad C_PAD may include a conductive material.

The cell structure CELL according to some example embodiments may include an upper structure US, a plurality of second bonding pads 450, and at least one second dummy pads 460 positioned on the lower surface of the cell wiring part 180. The upper structure US may include a plurality of upper barrier layers UB1 and UB2, a plurality of upper interlayer insulating layers 401, 402, and 403, a third upper insulation layer 423, and a second junction insulation layer 430 sequentially stacked in the third direction (the direction Z) on the lower surface of the bit line BL.

The upper structure US may be positioned on the lower surface of the cell wiring part 180. For example, the upper structure US may be positioned on the lower surface of the bit line BL. The upper structure US may be positioned between the bit line BL and the lower structure LS. The upper structure US may be connected to the peripheral structure PERI.

Below, the peripheral structure PERI is described.

The peripheral structure PERI may include a first cell substrate 200, a circuit element PTR positioned on the first cell substrate 200, a lower structure LS positioned on the first cell substrate 200, a plurality of first bonding pads 350 penetrating at least a portion of the lower structure LS, and at least one first dummy pads 360.

The lower structure LS may be positioned on the first cell substrate 200. For example, the lower structure LS may be positioned on the front surface of the first cell substrate 200. That is, the lower structure LS may be positioned between the cell structure CELL and the first cell substrate 200.

In some example embodiments, the lower structure LS may include a plurality of lower barrier layers LB1, LB2, and LB3, a plurality of lower interlayer insulating layers 301, 302, 303, and 304, a third lower insulation layer 323, and a first junction insulation layer 330 sequentially stacked in the third direction (the direction Z) on the first cell substrate 200.

In some example embodiments, the second junction insulation layer 430 and the plurality of second bonding pads 450 of the cell structure CELL, and the first junction insulation layer 330 and the plurality of first bonding pads 350 of the peripheral structure PERI may be joined by a hybrid junction like some example embodiments of FIG. 1 to FIG. 16.

Specifically, one surface of the peripheral structure PERI adjacent to the cell structure CELL may be composed of the plurality of first bonding pads 350 and the first junction insulation layer 330 as a junction surface with the cell structure CELL. One surface of the cell structure CELL adjacent to the peripheral structure PERI may be composed of the plurality of second bonding pads 450 and the second junction insulation layer 430 as a junction surface with the peripheral structure PERI.

One surface of the cell structure CELL and one surface of the peripheral structure PERI may be joined by a hybrid junction. Specifically, the plurality of first bonding pads 350 of the peripheral structure PERI and the plurality of second bonding pads 450 of the cell structure CELL may be joined in direct contact, thereby forming a metal junction. Also, the first junction insulation layer 330 of the peripheral structure PERI and the second junction insulation layer 430 of the cell structure CELL may be joined to form a junction insulation layer.

In this way, the plurality of first bonding pads 350 of the peripheral structure PERI and the plurality of second bonding pads 450 of the cell structure CELL may be joined to provide an electrical connection path between the peripheral structure PERI and the cell structure CELL. For example, by the upper wire UM1 and the lower wire LM1 and LM2, the bit line BL and/or the gate electrode 130 connected to the channel structure CH may be electrically connected to the circuit element PTR of the peripheral structure PERI.

At this time, in some example embodiments, the scribe lane area SLA, in which a plurality of first dummy pads 360 and a plurality of second dummy pads 460 are positioned may be positioned in a portion of the extension area EXT. The plurality of first dummy pads 360 and the plurality of second dummy pads 460 may be positioned apart from each other in the third direction (the direction Z), but is not limited thereto.

The first cell substrate 200 may include opposing front and back surfaces. The front side of the first cell substrate 200 may face the cell structure CELL. The back surface of the first cell substrate 200 may face the cell structure CELL.

The first cell substrate 200 may be a semiconductor substrate including a semiconductor material. For example, the first cell substrate 200 may be a semiconductor substrate made of a semiconductor material, or may be a semiconductor substrate in which a semiconductor layer is formed on a base substrate. For example, the first cell substrate 200 may be composed of monocrystalline or polycrystalline silicon, epitaxial silicon, germanium, or silicon-germanium, silicon on insulator (SOI), or germanium on insulator (GOI).

The circuit element PTR may be positioned on the first cell substrate 200. The circuit element PTR may include various circuit elements that control the operation of the memory cell structure provided in the cell structure CELL.

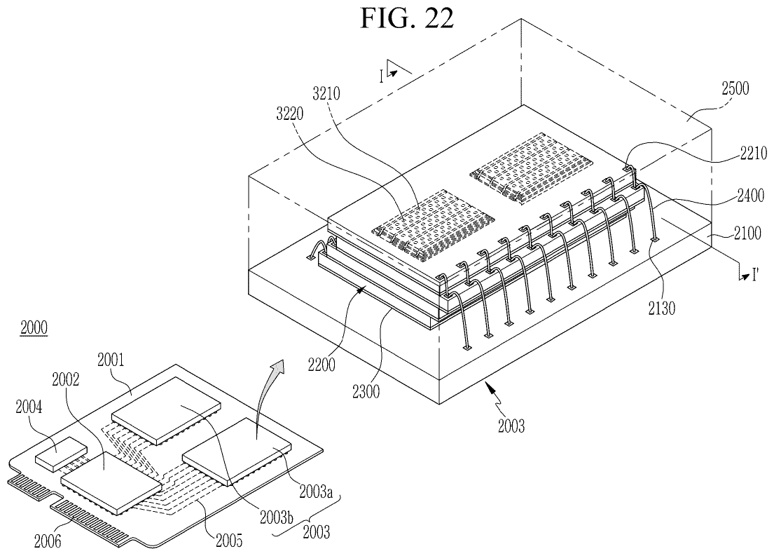

Hereinafter, an electron system including the semiconductor device according to some example embodiments will be described with reference to FIG. 21 to FIG. 22.

FIG. 21 is a schematic drawing of an electron system including a semiconductor device according to some example embodiments.

An electron system 1000 according to some example embodiments, as shown in FIG. 21, may include a semiconductor device 1100 and a controller 1200 electrically connected to the semiconductor device 1100. The electron system 1000 may be a storage device including one or a plurality of semiconductor devices 1100 or an electronic device including the storage device. For example, the electron system 1000 may be a solid state drive device (SSD), a universal serial bus (USB), a computing system, a medical device or a communication apparatus including one or a plurality of semiconductor devices 1100.

The semiconductor device 1100 may be a non-volatile memory device, and may be a NAND flash memory device, for example, as described with reference to FIG. 17 to FIG. 20. The semiconductor device 1100 may include a first structure 1100F and a second structure 1100S on the first structure 1100F. In some example embodiments, the first structure 1100F may be positioned next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT positioned between the lower transistors LT1 and LT2 and the upper transistors UT1 and UT2. The number of the lower transistors LT1 and LT2 and the number of the upper transistors UT1 and UT2 may vary according to some example embodiments.

In some example embodiments, the lower transistors LT1 and LT2 may include a ground select transistor, and the upper transistors UT1 and UT2 may include a string select transistor. The first and second gate lower lines LL1 and LL2 may be the gate electrodes of the lower transistors LT1 and LT2, respectively. The word line WL may be the gate electrode of the memory cell transistor MCT, and the gate upper lines UL1 and UL2 may be the gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through the first connection wiring 1115 that extends from the first structure 1100F to the second structure 1100S. The bit line BL may be electrically connected to the page buffer 1120 via the second connection wiring 1125, which extends to the second structure 1100S from the first structure 1100F.

In the first structure 1100F, the decoder circuit 1110 and the page buffer 1120 may perform control the operation on at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through the input/output pad 1101, which is electrically connected to the logic circuit 1130. The input/output pad 1101 may be electrically connected to the logic circuit 1130 via the input/output wiring 1135, which extends from the first structure 1100F to the second structure 1100S.

The controller 1200 may include a processor 1210, a NAND controller 1220, and a host interface 1230. According to some example embodiments, the electron system 1000 may include a plurality of semiconductor devices 1100, in this case, the controller 1200 may control the plurality of semiconductor devices 1100.

The processor 1210 may control the operation of the entire electron system 1000, including the controller 1200. The processor 1210 may operate according to a predetermined (or alternatively, desired or determined) firmware and control the NAND controller 1220 to access the semiconductor device 1100. The NAND controller 1220 may include a NAND interface 1221 that processes communications with the semiconductor device 1100. Through the NAND interface 1221, control instructions for controlling the semiconductor device 1100, data to be written to the memory cell transistor MCT of the semiconductor device 1100, data to be read from the memory cell transistor MCT of the semiconductor device 1100, etc. may be transmitted. The host interface 1230 may provide communication functions between the electron system 1000 and an external host. When receiving the control instruction from an external host through the host interface 1230, the processor 1210 may respond to the control instruction and control the semiconductor device 1100.

FIG. 22 is a perspective view schematically illustrating an electron system including a semiconductor device according to some example embodiments.

As shown in FIG. 22, an electron system 2000 according to some example embodiments may include a main substrate 2001, a controller 2002 mounted on the main substrate 2001, one or more semiconductor packages 2003, and a DRAM 2004. The semiconductor package 2003 and the DRAM 2004 may be interconnected with the controller 2002 by the wiring pattern 2005 formed on the main substrate 2001.

The main substrate 2001 may include a connector 2006 including a plurality of pins that are coupled to an external host. The number and arrangement of the plurality of pins in the connector 2006 may vary depending on the communication interface between the electron system 2000 and the external host. In some example embodiments, the electron system 2000 may communicate with an external host via any one of following interfaces such as a universal serial bus (USB), a peripheral component interconnect express (PCI-Express), a serial advanced technology attachment (SATA), or an M-Phy for a universal flash storage (UFS). In some example embodiments, the electron system 2000 may be operated by a power supplied from an external host through the connector 2006. The electron system 2000 may further include a power management integrated circuit (PMIC) that distributes the power supplied from the external host to the controller 2002 and the semiconductor package 2003.

The controller 2002 may write a data to or read a data from the semiconductor package 2003, and improve the operation speed of the electron system 2000.

The DRAM 2004 may be a buffer memory to alleviate the speed difference between the semiconductor package 2003, which is the data storage space, and the external host. The DRAM 2004 included in the electron system 2000 may also function as a type of cache memory and provide a space to temporarily store a data in the control operations for the semiconductor package 2003. When the electron system 2000 includes the DRAM 2004, the controller 2002 may further include a DRAM controller for controlling the DRAM 2004 in addition to the NAND controller for controlling the semiconductor package 2003.

The semiconductor package 2003 may include a first and a second semiconductor packages 2003a and 2003b which are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, a semiconductor chip 2200 on the package substrate 2100, an adhesive layer 2300 positioned on the lower surface of each of the semiconductor chips 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board (PCB) including a package upper pad 2130. Each semiconductor chip 2200 may include an input/output pad 2210. The input/output pad 2210 may correspond to the input/output pad 1101 of FIG. 21. Each semiconductor chip 2200 may include a gate stacking structure 3210 and a channel structure 3220. The semiconductor chip 2200 may each include the semiconductor device. Described with reference to FIG. 17 to FIG. 20.

In some example embodiments, the connection structure 2400 may be a bonding wire that electrically connects the input/output pad 2210 and the package upper pad 2130. Therefore, in each of the first and second semiconductor packages 2003a and 2003b, the semiconductor chips 2200 may be electrically connected to each other in a bonding wire manner and be electrically connected to the package upper pad 2130 of the package substrate 2100. According to some example embodiments, in each of the first and second semiconductor packages 2003a and 2003b, the semiconductor chips 2200 may be electrically connected to each other by a connection structure including a through silicon via (TSV) instead of a bonding wire type connection structure 2400.

In some example embodiments, the controller 2002 and the semiconductor chip 2200 may be included in a single package. For example, the controller 2002 and the semiconductor chip 2200 may be mounted on a separate interposer substrate from the main substrate 2001, and the controller 2002 and the semiconductor chip 2200 may be connected to each other by a wiring formed on the interposer substrate.

While this disclosure has been described in connection with what is presently considered to be example embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a first substrate structure and a second substrate structure on the first substrate structure, the first substrate structure including
a first substrate including a cell area and a scribe lane area surrounding the cell area,
a plurality of first bonding pads over the cell area of the first substrate, and
a plurality of first dummy pads on the first substrate in the scribe lane area, the second substrate structure including
a second substrate on the first substrate, and
a plurality of second bonding pads between the first substrate and the second substrate, and joined with the plurality of first bonding pads to each other, and
a sum of the areas of the plurality of first dummy pads per a unit area in the scribe lane area is greater than or equal to a sum of the areas of the plurality of first bonding pads per a unit area in the cell area.

2. The semiconductor device of claim 1, wherein:
a diameter of the plurality of first bonding pads is smaller than a diameter of the plurality of first dummy pads.

3. The semiconductor device of claim 1, wherein:
a spacing between the plurality of first bonding pads is larger than a spacing between the plurality of first dummy pads.

4. The semiconductor device of claim 1, wherein:
a thickness of at least some of the plurality of first dummy pads is less than a thickness of the plurality of first bonding pads.

5. The semiconductor device of claim 1, wherein:
the second substrate structure further includes a plurality of second dummy pads between the first substrate and the second substrate and overlaps the plurality of first dummy pads.

6. The semiconductor device of claim 5, wherein:
a sum of the areas of the plurality of second dummy pads per a unit area is greater than or equal to a sum of the areas of the plurality of second bonding pads per a unit area.

7. The semiconductor device of claim 1, wherein:
the first substrate structure further includes a first junction insulation layer surrounding the plurality of first bonding pads and the plurality of first dummy pads,
the second substrate structure further includes a second junction insulation layer surrounding the plurality of second bonding pads, and
the first junction insulation layer is in contact with the second junction insulation layer.

8. The semiconductor device of claim 7, wherein:
the first junction insulation layer includes a recessed portion concave toward the first substrate in the scribe lane area.

9. The semiconductor device of claim 7, wherein:
the first junction insulation layer and the second junction insulation layer include a same material, and
the plurality of first bonding pads and the plurality of second bonding pads include a same material.

10. The semiconductor device of claim 1, wherein the first substrate structure further includes
a lower wire above the first substrate in the cell area,
a lower insulation layer between the lower wire and the plurality of first bonding pads,
a first bonding via penetrating the lower insulation layer and connecting the plurality of first bonding pads and the lower wire, and
the lower wire is electrically floating from the plurality of first dummy pads.

11. The semiconductor device of claim 10, wherein:
the first substrate structure further includes a first dummy via penetrating the lower insulation layer and connected to the plurality of first dummy pads, and
the first dummy via includes a same material as each of the plurality of first dummy pads and is formed integrally.

12. The semiconductor device of claim 1, wherein:
the scribe lane area includes
a first area apart from the cell area and including the plurality of first dummy pads, and
a second area between the cell area and the first area and including the plurality of first dummy pads,
the sum of the areas of the plurality of first dummy pads per a unit area in the second area is greater than the sum of the areas of the plurality of first bonding pads per a unit area in the cell area, and
the sum of the areas of the plurality of first dummy pads per a unit area in the first area is greater than the sum of the areas of the plurality of first dummy pads per a unit area in the second area.

13. The semiconductor device of claim 1, wherein:
the scribe lane area includes
a key area separated from the cell area, and
a first division area surrounding the key area and including the plurality of first dummy pads, and
a second division area between the first division area and the cell area and including the plurality of first dummy pads, and
the sum of the areas of the plurality of first dummy pads per a unit area in the first division area is greater than the sum of the areas of the plurality of first bonding pads per a unit area in the second division area.

14. A semiconductor device comprising:
a first substrate structure and a second substrate structure above the first substrate structure,
the first substrate structure including
a first substrate including a plurality of cell areas and a scribe lane area between the plurality of cell areas,
a plurality of first bonding pads on the first substrate in the plurality of cell areas,
a plurality of first dummy pads above the first substrate in the scribe lane area, and
a first junction insulation layer surrounding the plurality of first bonding pads and the plurality of first dummy pads,
the second substrate structure including
a second substrate on the first substrate,
a plurality of second bonding pads between the first substrate and the second substrate and joined with the plurality of first bonding pads each other, and
a second junction insulation layer surrounding the plurality of second bonding pads and joined with at least a portion of an upper surface of the first junction insulation layer, and
a sum of the areas of the plurality of first dummy pads per a unit area in the cell area is greater than or equal to a sum of the areas of the plurality of first bonding pads per a unit area.

15. The semiconductor device of claim 14, wherein the second substrate structure further includes
a plurality of second dummy pads between the first substrate and the second substrate and overlapping the plurality of first dummy pads, and
at least some of the plurality of second dummy pads are spaced in a vertical direction from the plurality of first dummy pads.

16. The semiconductor device of claim 15, wherein a sum of the areas of the plurality of second dummy pads per a unit area is greater than or equal to a sum of the areas of the plurality of second bonding pads per a unit area.

17. The semiconductor device of claim 15, wherein a thickness of at least some of the plurality of first dummy pads is less than a thickness of the plurality of first bonding pads.

18. The semiconductor device of claim 14, wherein:
the first junction insulation layer includes a same material as the second junction insulation layer, and
the plurality of first bonding pads and the plurality of second bonding pads include the same material.

19. A semiconductor device comprising:
a first substrate structure and a second substrate structure above the first substrate structure,
the first substrate structure including
a first substrate including a cell area and a scribe lane area surrounding the cell area,
a plurality of first bonding pads above the cell area of the first substrate,
a plurality of first dummy pads above the scribe lane area of the first substrate, and
a first junction insulation layer surrounding the plurality of first bonding pads and the plurality of first dummy pads,
the second substrate structure including
a second substrate on the first substrate,
a plurality of second bonding pads between the first substrate and the second substrate and joined with the plurality of first bonding pads each other, and
a second junction insulation layer surrounding a plurality of second bonding pads and junction with at least a portion of an upper surface of the first junction insulation layer in the cell area,
the first junction insulation layer including a recessed portioned concave toward the first substrate in the scribe lane area, and
a thickness of at least some of the plurality of first dummy pads is less than a thickness of the plurality of first bonding pads.

20. The semiconductor device of claim 19, wherein at least a portion of the first junction insulation layer in the scribe lane area includes a portion spaced apart from the second junction insulation layer in a vertical direction.
